(19) United States
(12) Patent Application Publication
(10) Pub. No.: US 2023/0309265 A1
(43) Pub. Date: Sep. 28, 2023

(54) FLEXIBLE THERMAL SYSTEM

(71) Applicant: Meta Platforms Technologies, LLC, Menlo Park, CA (US)

(72) Inventors: Michael Nikkhoo, Saratoga, CA (US); Brian Toleno, Cupertino, CA (US)

(21) Appl. No.: 17/701,577

(22) Filed: Mar. 22, 2022

(51) Int. Cl. H05K 7/20

(52) U.S. Cl. CPC H05K 7/20336

(57) ABSTRACT

A thermal system configured to mechanically bend and provide a thermal conduit to transfer heat through an electronic device, and an electronic device having a bent or curved profile or a mechanical articulation or coupler between a first location and a second location, and equipped with a thermal system configured to extend through or along the bent or curved profile or mechanical articulation or coupler of the electronic device and transfer heat from the first location of the electronic device to the second location of the electronic device

### BACKGROUND

Recent advances in battery technology have enabled computationally powerful portable electronic devices, which generate considerable amounts of heat. The increased heat generated by these devices, coupled with the continual demand for smaller and lighter devices makes it difficult to adequately dissipate heat from the portable electronic devices.

### BRIEF DESCRIPTION OF THE DRAWINGS

The detailed description is described with reference to the accompanying figures. In the figures, the left-most digit(s) of a reference number identifies the figure in which the reference number first appears. The use of the same reference numbers in different figures indicates similar or identical components or features.

FIG. 1 illustrates an example electronic device usable to implement techniques such as those described herein.

FIGS. 2A and 2B are simplified schematic diagrams of example cross-sectional views of thermal systems including a heat pipe with integrated bellows as a flexible portion.

FIG. 3 is a simplified schematic diagram of an example cross-sectional view of a thermal system that includes a connecting bellows operably connecting two heat pipes.

FIGS. 4A-4E are simplified schematic diagrams of example cross-sectional views of thermal systems including a hollow, flexible connector operably connecting two heat pipes.

FIG. 5 is a simplified schematic diagram of an example cross-sectional view of a thermal system including a solid connector transferring heat from one heat pipe to another heat pipe.

FIGS. 6A-6F illustrate simplified schematic diagrams of an example process for forming the structure of a thermal system as described herein.

FIGS. 7A and 7B are simplified schematic diagrams of example electronic devices having one or more thermal systems as described herein extending across a hinge or other coupler that provides a mechanical articulation.

### DETAILED DESCRIPTION

This application describes a bendable thermal system configured to mechanically bend and provide a thermal conduit to spread heat through an electronic device, and an electronic device having a bent or curved profile or a mechanical articulation between a first location and a second location, and equipped with a thermal system configured to extend through or along the bent or curved profile or mechanical articulation of the electronic device and spread heat from the first location of the electronic device to the second location of the electronic device.

In examples, an electronic device may include a device having a curved or bent portion such as an angled side or element. In examples, an electronic device may include a coupler configured to provide a mechanical articulation such as a hinge, fold, pivot pins, or other bendable, flexible, swinging, or rotatable structures.

In examples, the thermal system as described may include a thermal system configured to include one or more flexible portions. In examples, a flexible portion may include a bendable member. In examples, a bendable member may include an elongated member such as a solid connector, a hollow connector, a bellows, or any combination thereof. In examples, a flexible portion may include a bellows. In examples, a flexible portion of the thermal system may be provided at an adiabatic region of a thermal management component or of the thermal system.

In examples, the bendable member may include a fiber wick extending through at least a portion of a length of its internal volume to promote capillary action. In examples, the fiber wick extend across only the length of the bendable member. In examples, a fiber wick may extend beyond the bendable member. In examples, the fiber wick may extend through at least one thermal management component and/or at least the condenser side of a thermal management component in addition to the bendable member. In examples, the fiber wick may extend along the full internal length of the thermal system. In examples, a fiber wick may be coated. In examples, the fiber wick may be connected to other wick structures that reach the bendable member.

In examples, the bendable member may include a highly thermally conductive material. In examples, the bendable member may include a material that has a thermal conductivity of 25 W/mK or higher. In examples, the bendable member may include a material having a thermal conductivity within the range of 25 to 40 W/mK, for example, 25 to 35 W/mK. In examples, the bendable member may include a material having a thermal conductivity equal to or greater than 40 W/mK. In examples, the bendable member may include a high molecular weight polymer. In examples, a high molecular weigh polymer may include a polymer having a molecular weight of about 5,000,000 gr/mol or higher. In examples, the bendable member may include a metal such as nickel.

In examples, the bendable member may be metal plated. In examples, the bendable member may be copper plated. Plating of a bendable member may enhance adhesion between a bendable member and a connected structure.

In examples, the bendable member has an overall thickness or an internal width that is 1 mm or less. For examples, the bendable member may have an overall thickness or an internal diameter of 1 mm, 0.9 mm, 0.8 mm, 0.7 mm, 0.6 mm, 0.5 mm, 0.4 mm, 0.3 mm, 0.2 mm, 0.1 mm. For purposes of this description an overall thickness should be understood to be a distance between two directly opposite outer surfaces facing in opposite directions. For purposes of this description an internal width should be understood to be the distance between two directly opposite internal surfaces facing each other.

In examples, the thermal system may include a single thermal management component such as a heat pipe or vapor chamber. In examples, the thermal system may include two or more thermal management components. In examples, the thermal system may include two or more fluidly connected thermal management components, non-fluidly connected thermal management components, or a combination of both. In examples, the flexible portion of the thermal system, such as a bendable member or a bellows may include of the same or different material used for the shell of a thermal management components.

In examples, aside from the flexible portion(s), the thermal system may include rigid structure(s). In examples, a thermal system may include a thermal management component with one or more integrated bellows wherein the thermal management component includes a rigid, non-bendable structure outside the integrated bellows. In examples, a thermal system may include two or more thermal management components connected together by one or more flexible portions wherein the thermal management components include rigid structures. Any combination of these may also be possible.

In examples, a thermal system may include one or more spacers inside a flexible portion such as a hollow connector or a bellows. In examples, the one or more spacers inside a bellows may be configured to maintain fluid flow through the bellows while the bellows is in a bent position. In examples, the one or more spacers inside a bellows may be configured to not prevent fluid flow through the bellows and/or configured to allow or not prevent insertion of a wick through at least a portion of an internal volume of the bellows. In examples, one or more spacers may be provided above a wick that is provided inside the flexible portion of the thermal system. In examples, the one or more spacers may be configured to prevent pinching or collapse of the bellows. In examples, the one or more spacers inside a hollow connector or a bellows may include hydrophobic surface to enhance flow of a working fluid through the hollow connector or bellows.

In examples, the thermal system may include one or more wicks. In examples, a wick may include one or more corrugated surfaces, a mesh, one or more fibers, or any combination thereof. In examples, each thermal management component of a thermal system may include its own wick. In examples, a wick may extend from at least a first thermal management component of the thermal system to at least a second thermal management component of the thermal system. In examples, a wick may extend through a bellows. In examples, a wick may extend through two or more thermal management components and one or more bellows.

In examples, an electronic device may be configured to include a thermal system as described herein. In examples, the thermal system may be configured to spread heat across different portions of the electronic device. In examples, spreading heat across different portions of the electronic device can enhance the dissipation of heat from the electronic device to the environment. In examples, spreading heat across different portions of the electronic device may include transferring heat from a first region of the electronic device to a second region of the electronic device. In examples, spreading heat across different portions of the electronic device may preempt overheating at one location of the electronic device. In examples, the thermal system may cause the electronic device to achieve or advance toward an isothermal condition.

Examples of a thermal management component of a thermal system may include a heat pipe or a vapor chamber. For ease of reference, in the drawings described herein reference is made to a heat pipe; however, the same discussion apply equally to a vapor chamber.

In examples, a thermal management component may be configured to hold a working fluid (e.g., water, ionized water, glycol/water solutions, alcohol, acetone, dielectric coolants, etc.) that may be used to actively remove heat from components thermally coupled to the thermal management component. In examples, a thermal management component may have an internal diameter or internal width in the range of 5 to 20 mm In one example, a thermal management component may include titanium, copper, or any combination thereof. In examples, a thermal management component may be larger or smaller than the ranges listed and/or can be made by additional or alternative manufacturing techniques.

In some examples, the working fluid may be circulated through a thermal management component via capillary action and thermal differentials throughout the thermal system. In some examples, the working fluid may be actively pumped throughout the thermal management component to increase the rate at which the working fluid circulates. In some examples, a thermal management component may additionally or alternatively include and/or be coupled to one or more other thermal management features (e.g., heatsinks, fins, radiators, fans, compressors, etc.) which may further increase the ability of the thermal management component to remove heat from components of the electronic device.

In examples, an electronic device may include a first elongated portion, a second elongated portion, and a coupler interposed between the first elongated portion and the second elongated portion. The coupler may be attached to the first elongated portion and the second elongated portion and may be configured to provide mechanical articulation of the second elongated portion relative to the first elongated portion. A thermal system may extend from the first elongated portion to the second elongated portion and may be configured to extend across the coupler. The thermal system may include a flexible portion having a fiber wick extending through at least a portion of a hollow internal space of the flexible portion.

In examples, the thermal system may include a first thermal management component having a first heat pipe, a first vapor chamber, or both.

In examples, the electronic device may include a bellows as an integral part of the first thermal management component.

In examples, the thermal system may include a second thermal management component having a second heat pipe, second vapor chamber, or both.

In examples, the flexible portion may be connected to one end of the first thermal management component and one end of the second thermal management component.

In examples, the flexible portion may include a connecting bellows including nickel.

In examples, the flexible portion may include a hollow connector.

In examples, the hollow connector may include a polypropylene, a polyethylene terephthalate, or a polyimide. In examples, the polyimide may include a metal laminated poly-oxydiphenylene-pyromellitimide. In examples, the polyethylene terephthalate may include a molecular weight of at least about 5,000,000 gr/mol.

In examples, the thermal system may include at least one of a mesh wick extending from the first thermal management component to the second thermal management component and through the flexible portion.

In examples, the fiber wick may include a metal coating.

In examples, the first elongated portion may include a portion of a frame of a head-mounted device and the second elongated portion may include a strap or temple arm of the head mounted device.

In examples, a bendable thermal system may include a first longitudinal end, a second longitudinal end, a flexible portion disposed between the first longitudinal end and the second longitudinal end, and a fiber wick provided inside the flexible portion.

In examples, the flexible portion may include polyethylene terephthalate having a thermal conductivity of 25 W/mK or higher.

In examples, the flexible portion may include a metal laminated polyimide.

In examples, the flexible portion may include nickel.

In examples, the bendable thermal system may include a thermal management component selected from a single heat pipe or a single vapor chamber, wherein the thermal management component may include the first longitudinal end and the second longitudinal end.

In examples, a bendable thermal system may include a first thermal management component that may have a first sealed, rigid structure, a second thermal management component that may have a second sealed rigid structure, and a solid connector connected to one end of the first thermal management component and to one end of the second thermal management component, the solid connector configured to transfer heat from the first thermal management component to the second thermal management component.

In examples, the solid connector may include graphite, titanium, or a combination thereof.

These and other aspects are described further below with reference to the accompanying drawings and appendices. The drawings are merely example implementations and should not be construed to limit the scope of the claims. For example, while examples are illustrated in the context of a head-mounted electronic device, the techniques may be used in association with any electronic device.

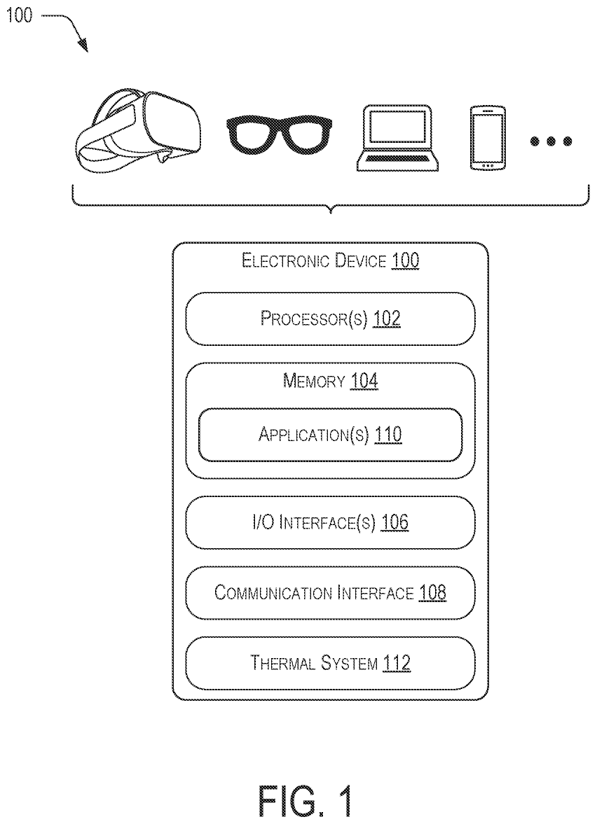

FIG. 1 illustrates an example electronic device 100 usable to implement techniques such as those described herein. The electronic device 100 may be representative of a wearable device such as a watch or a head-mounted device like an extended reality headset or glasses, or a portable device such as a laptop computer, a mobile device such as a tablet or mobile phone, or any other electronic device such as those described throughout this application.

As shown, the electronic device 100 may include one or more electronic components such as processors 102, memory 104, input/output interfaces 106 (or “I/O interfaces 106”), and communication interfaces 108, which may be communicatively coupled to one another by way of a communication infrastructure (e.g., a bus, traces, wires, etc.). While the electronic device 100 is shown in FIG. 1 having a particular configuration, the components illustrated in FIG. 1 are not intended to be limiting. The various components can be rearranged, combined, and/or omitted depending on the requirements for a particular application or function. Additional or alternative components may be used in other examples.

In some examples, the processor(s) 102 may include hardware for executing instructions, such as those making up a computer program or application. For example, to execute instructions, the processor(s) 102 may retrieve (or fetch) the instructions from an internal register, an internal cache, the memory 104, or other computer-readable media, and decode and execute them. By way of example and not limitation, the processor(s) 102 may comprise one or more central processing units (CPUs), graphics processing units (GPUs), holographic processing units, microprocessors, microcontrollers, integrated circuits, programmable gate arrays, or other hardware components usable to execute instructions.

The memory 104 is an example of computer-readable media and is communicatively coupled to the processor(s) 102 for storing data, metadata, and programs for execution by the processor(s) 102. In some examples, the memory 104 may constitute non-transitory computer-readable media such as one or more of volatile and non-volatile memories, such as Random-Access Memory (“RAM”), Read-Only Memory (“ROM”), a solid-state disk (“SSD”), Flash, Phase Change Memory (“PCM”), or other types of data storage. The memory 104 may include multiple instances of memory and may include internal and/or distributed memory. The memory 104 may include removable and/or non-removable storage. The memory 104 may additionally or alternatively include one or more hard disk drives (HDDs), flash memory, Universal Serial Bus (USB) drives, or a combination these or other storage devices.

As shown, the electronic device 100 includes one or more I/O interfaces 106, which are provided to allow a user to provide input to (such as touch inputs, gesture inputs, key strokes, voice inputs, etc.), receive output from, and otherwise transfer data to and from the electronic device 100. Depending on the particular configuration and function of the electronic device 100, the I/O interface(s) 106 may include one or more input interfaces such as keyboards or keypads, mice, styluses, touch screens, cameras, microphones, accelerometers, gyroscopes, inertial measurement units, optical scanners, other sensors, controllers (e.g., handheld controllers, remote controls, gaming controllers, etc.), network interfaces, modems, other known I/O devices or a combination of such I/O interface(s) 106. Touch screens, when included, may be activated with a stylus, finger, thumb, or other object. The I/O interface(s) 106 may also include one or more output interfaces for presenting output to a user, including, but not limited to, a graphics engine, a display (e.g., a display screen, projector, holographic display, etc.), one or more output drivers (e.g., display drivers), one or more audio speakers, and one or more audio drivers. In certain examples, I/O interface(s) 106 are configured to provide graphical data to a display for presentation to a user. The graphical data may be representative of one or more graphical user interfaces and/or any other graphical content as may serve a particular implementation. By way of example, the I/O interface(s) 106 may include or be included in a wearable device, such as a head-mounted display (e.g., headset, glasses, helmet, visor, etc.), a suit, gloves, a watch, or any combination of these, a handheld electronic device (e.g., tablet, phone, handheld gaming device, etc.), a portable electronic device (e.g., laptop), or a stationary electronic device (e.g., desktop computer, television, set top box, a vehicle electronic device). In some examples, the I/O interface(s) 106 may be configured to provide an extended reality environment or other computer-generated environment.

The electronic device 100 may also include one or more communication interface(s) 108. The communication interface(s) 108 can include hardware, software, or both. In examples, communication interface(s) 108 may provide one or more interfaces for physical and/or logical communication (such as, for example, packet-based communication) between the electronic device 100 and one or more other electronic devices or one or more networks. As an example, and not by way of limitation, the communication interface(s) 108 may include a network interface controller (NIC) or network adapter for communicating with an Ethernet or other wire-based network and/or a wireless NIC (WNIC) or wireless adapter for communicating with a wireless network, such as a WI-FI adapter. In examples, communication interface(s) 108 can additionally include a bus, which can include hardware (e.g., wires, traces, radios, etc.), software, or both that communicatively couple components of electronic device 100 to each other. In examples, the electronic device 100 may include additional or alternative components that are not shown, such as, but not limited to, a power supply (e.g., batteries, capacitors, etc.), a housing or other enclosure to at least partially house or enclose any or all of the components.

The memory 104 may store one or more applications 110, which may include, among other things, an operating system (OS), productivity applications (e.g., word processing applications), communication applications (e.g., email, messaging, social networking applications, etc.), games, or the like. The application(s) 110 may be implemented as one or more stand-alone applications, as one or more modules of an application, as one or more plug-ins, as one or more library functions application programming interfaces (APIs) that may be called by other applications, and/or as a cloud-computing model. The application(s) 110 can include local applications configured to be executed locally on the electronic device, one or more web-based applications hosted on a remote server, and/or as one or more mobile device applications or “apps.”

In examples, the electronic device 100 may also include a thermal system 112 as described herein, to which the other electronic components such as the processor(s) 102, memory 104, I/O device(s) 106, and/or communication interface(s) 108 can be thermally coupled. In examples, the thermal system 112 may be thermally conductive and configured to spread heat generated by the one or more other components. The thermal system 112 can be made of a relatively light weight, rigid material such as any of those described herein, and may be configured to exhibit manufacturing tolerances suitable for mounting precision optical components (e.g., lenses, display screens, mirrors, gratings, optical fibers, light pipes, etc.).

In examples, the electronic device 100 may include one or more static curved portions and/or mechanical articulation that pivot, rotate, bend, flex, or otherwise translate across a plane. In examples, a coupler configured to provide mechanical articulation provided in an electronic device may include a hinge, fold, joint, pivoting element, or other flexible joint and/or bendable member. In examples, a thermal system 112 may extend through at least a portion of a static curved portion or a mechanical articulation such as one provided by coupler. In examples, a thermal system 112 may extend from a first region of the electronic device 100 to a second region of the electronic device 100, wherein a static curved portion or a mechanical articulation is located between the first region and the second region of the electronic device 100. In examples, the thermal system 112 extends from a first elongated and/or planar portion of electronic device 100, across and/or through a static curved portion or coupler that provides a mechanical articulation and reach a second elongated and/or planar portion of the electronic device 100. In examples, the portion of a thermal system 112 that extends through and/or across a static curved portion or mechanical articulation may include at least a portion of a flexible portion.

For example, an example electronic device 100 may be as an extended reality headset or glasses. The electronic device may include a first elongated and/or planar portion, such as a face front portion, and a second elongated and/or planar portion, such as a temple arm or side portion, with a static curved portion or mechanical articulation such as a hinge or fold between the first elongated and/or planar portion and the second elongated and/or planar portion. In examples, a thermal system 112 may be provided to extend from first flat portion to second flat portion and across or through a static curved portion or mechanical articulation or coupler. In examples, the electronic device may include one or more of the previously discussed components (e.g., processor(s) 102, memory 104, I/O device(s) 106, and/or communication connection(s) 108) at least at or near first flat portion. In examples, the one or more components may be thermally coupled at least to a portion of thermal system 112 that extends across first flat portion. As the electronic device is used, heat generated from the one or more components in the first flat portion may be transferred to the portion of the thermal system 112 located in the first flat portion. In examples, thermal system 112 may be configured to transfer or spread the heat from the one or more components to the second flat portion of the electronic device. In examples, heat may be transferred within thermal system 112 via capillary action and/or thermal conduction from an evaporator region to a condenser region, from a first heat pipe to a second heat pipe, or any combination thereof. In examples, the heat transferred within thermal system 112 may transfer across one or more flexible portions. In examples, a flexible portion may be located at an adiabatic region of the thermal system 112.

In examples, a thermal system may include one or more thermal management components and one or more flexible portions. In examples, the thermal system may include a single thermal management component or two or more fluidly connected thermal management components. In examples, a thermal management component may have an internal diameter and/or internal width ranging from sub-millimeter to 20 mm, for example ranging from 0.15 mm to 1 mm, 1 mm to 2 mm, 2 mm to 3 mm, 3 mm to 4 mm, or 5 mm to 10 mm In examples, a flexible portion of the thermal system may be an integral part of a thermal management component or may be connected to a thermal management component. In examples, a flexible portion may be provided between two thermal management components. In examples, a flexible portion may include a bendable member that may be configured to accommodate axial, radial, lateral, and/or angular displacement. In examples, a flexible portion may be hollow or solid. In examples, a hollow flexible portion may have an internal diameter or internal width similar to that of one or more thermal management component it connects or of which it is part. In examples, a hollow flexible portion may have an internal diameter or internal width of about 0.15 mm to 20 mm, for example ranging from 0.15 mm to 1 mm, 0.20 mm to 1 mm, 0.30 mm to 1 mm, 0.5 mm to 1 mm, 0.7 mm to 1 mm, 1 mm to 2 mm, 2 mm to 3 mm, 3 mm to 4 mm, or 5 mm to 15 mm In examples, the hollow flexible portion may have an internal diameter or internal width that is the same size or larger than as at least a thermal management component of which it is part or to which it is connected. In examples, the hollow flexible portion may have an internal diameter or internal width that is less than 1 mm or sub-millimeter. In examples, the internal diameter or internal width of the hollow flexible portion is at least 0.15 mm. For purposes of this disclosure an internal width is shortest distance between two opposite sides of an internal surface of a flexible portion when the flexible portion is not in a bent position. In examples, the flexible portion may have a length ranging from about 0.2 mm to about 3 mm, for example 0.2 mm, 0.3 mm, 0.4 mm, 0.5 mm, 0.6 mm, 0.7 mm, 0.8 mm, 0.9 mm, 1 mm, 1.5 mm, 2 mm, 3 mm or a range defined by any two of these example measurements.

In examples, thermal management component may include a substantially rigid, light weight structural element. A thermal management component can be sized and shaped to any desired dimensions for a given design architecture. In examples, a thermal management component may include an outer shell. In examples, an outer shell to a thermal management component may include a high thermally conductive material. In examples, an outer shell of a thermal management component may include a metal such as, titanium, copper, aluminum, magnesium, steel, or any alloys and/or combinations thereof. In examples, the copper may be oxygen free copper (OFC). In examples, an outer shell of thermal management component may include high strength polymers (such as polyamideimide (PAI), polyetherimide (PEI), polyetheretherketone (PEEK), polyphenylene sulfide (PPS), Nylon, with or without fiber reinforcement), polyurethane, polypropylene, polyimide, polyethylene terephthalate (PET), composites such as carbon fiber or fiberglass, or any combination thereof. Other materials may also be used.

In examples, a thermal management component may include a fluid to improve heat transfer and/or heat dissipation as described with respect to thermal management component herein. The fluid may be any suitable fluid to transfer heat. In examples, the fluid may be dihydrogen monoxide (i.e. water), deionized water, an aqueous solution such as for example solutions of ethylene glycol and water or propylene glycol and water, an alcohol, or an organic fluid such as for example acetone, dielectric coolants, and perfluorinated carbons solution. Other fluids may also be implemented.

In examples, a thermal system and/or a thermal management component comprised in a thermal system may include one or more nodes (e.g., pads, tabs, other mounting surfaces) on an outer shell of a thermal management component. In examples, one or more nodes may be used to couple one or more electronic structures and/or intervening layers to a thermal system. In examples, one or more nodes may be formed by machining surfaces of a thermal system and/or a thermal management component, welding and/or brazing them to thermal system and/or a thermal management component, fastening them to the thermal system and/or a thermal management component using mechanical fasteners (e.g., screws, rivets, snap connections, etc.), additively manufacturing them onto the thermal system and/or to a thermal management component, or by any other process.

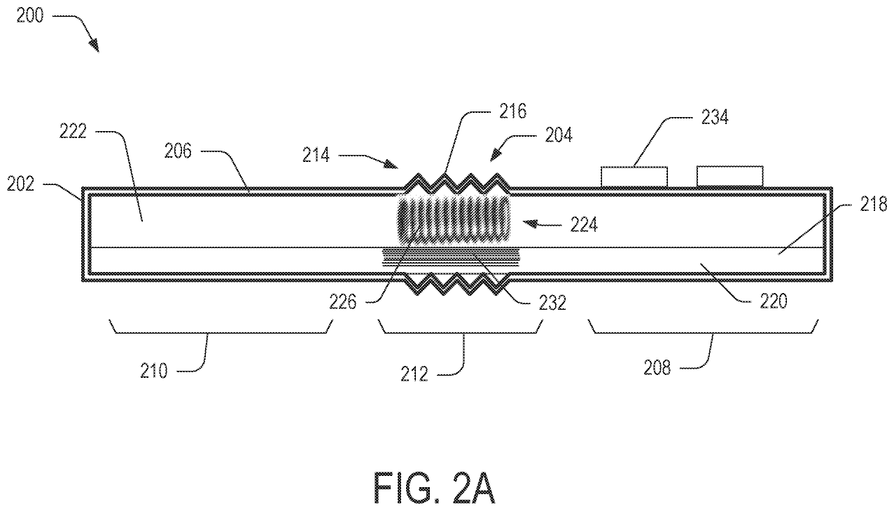

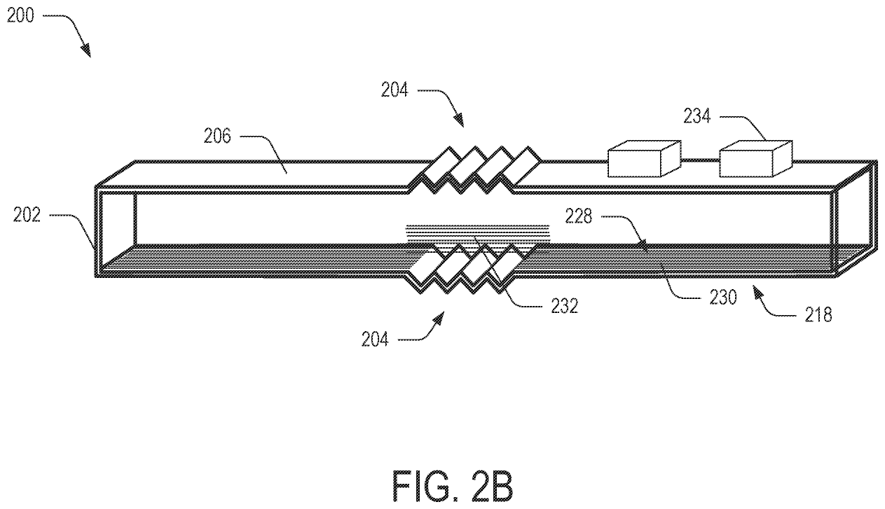

FIG. 2A illustrates an example of a thermal system 200 including a thermal management component, for example, a heat pipe 202, and a bellows 204. In examples, the thermal system 200 may be a single thermal management component. In examples, as illustrated, the thermal system 200 may be a continuous heat pipe 202. In examples, heat pipe 202 may include an outer shell 206. In examples, outer shell 206 may be a metal outer shell. In examples, outer shell 206 may include a metal such as copper, copper alloy, titanium, titanium alloy, or any combination thereof. Although not shown, heat pipe 202 may include a working fluid as previously described.

In examples, heat pipe 202 may have an evaporation or “hot” side 208 where heat is transferred from an electronic component to the heat pipe 202, and a condensation or “cold” side 210 where heat is spread from the heat pipe. In examples, extending between evaporation side 208 and condensation side 210, heat pipe 202 may include an adiabatic region 212. In examples, adiabatic region 212 may include a region where the heat pipe 202 transitions from the evaporation side 208 to the condensation side 210.

In examples, one or more electronic components 234 (e.g. processors, memory, I/O device(s), and/or communication connection(s)) may be thermally coupled to at least a portion of the heat pipe. In examples, one or more electronic components 234 are connected to an evaporator side 208 of heat pipe 202, to a condensation side 210 of heat pipe 202, to an adiabatic region 212 of heat pipe 202, or any combination thereof. Illustrated, one or more electronic components 234 are connected to an evaporator side 208 of heat pipe 202.

In examples as shown in FIG. 2A, a bellows 204 may be an integral part of the heat pipe 202. In examples, heat pipe 202 may include more than one integrated bellows 204. In examples, a bellows 204 may be a mechanical bellows configured to accommodate a flexural and/or bending motion. In examples, apart from the bellows 204, heat pipe 202 may include a rigid structure. In examples, a bellows 204 may be made of metal. In examples, a bellows 204 may include the same material as outer shell 206. In examples, as shown, a bellows 204 may be a portion of outer shell 206.

In examples, a bellows 204 may be provided at a location at which the heat pipe 202 is meant to bend when in the electronic device. In examples, the bending may be stationary to allow heat pipe 202 to extend around an edge or corner of the electronic device. In examples, a bellows 204 may be located at a portion of heat pipe 202 that extends along and/or through a mechanical articulation such as may be provided by a coupler of the electronic device. In this manner, the heat pipe 202 may be able to bend and accommodate the movement of the mechanical articulation, such as the rotation of a hinge or bending of a fold.

In examples, a bellows 204 may be located at an adiabatic region 212 of heat pipe 202. In examples, a bellows 204 is located between an evaporation side 208 of heat pipe 202 and a condensation side 210 of heat pipe 202. In examples, a bellows 204 does not block or substantially interfere with the capillary action between the evaporation side 208 and condensation side 210 of heat pipe 202.

In examples, a bellows 204 may be an integral part of heat pipe 202 by being formed as part of an outer shell 206 of heat pipe 202. In examples, a bellows 204 may be formed by metal folds, ridges, or a pleated pattern 214 along at least a portion of outer shell 206. In examples, metal folds, ridges, or pleats may be formed by any suitable process including, without limitation, heat press, forging, casting, shearing, bending, or other metalworking processes that can achieve the pleated pattern. In examples, one or more folds, ridges, or pleats 216 extends across one or more sides of outer shell 206. In examples, one or more pleats 216 extend across a portion of a top surface, a portion of a bottom surface, a portion of a first side surface, a portion of a second side surface, or any combination thereof. In examples, one or more pleats 216 extend along the full perimeter of a portion of an outer shell 206. In examples, one or more pleats 216 extend around of a portion of an outer shell 206 in a width direction of the heat pipe 202, a length direction of the heat pipe 202, or both.

In examples, a thermal management component may include a wick. In examples, a wick may enhance capillary action to transfer a fluid from a first side of the thermal management component to a second side of the thermal management component. In examples, a wick may have a water surface energy such that it exhibits hydrophilicity at an evaporation side of the thermal management component and hydrophobicity at a condensation side of the thermal management component. In examples, the surface energy and thus exhibited hydrophilicity characteristics of a wick may gradually vary from a first end of an adiabatic region to a second end, opposite the first end, of the adiabatic region. In examples, the hydrophilicity of a wick may be higher at one end of the adiabatic region than at the opposite end of the adiabatic region. In examples, the surface energy of a wick at an portion of the adiabatic region adjacent an evaporation side of a thermal management component may be similar or close to the surface energy of the wick at the evaporation side of the thermal management component, while the surface energy of a wick at an portion of the adiabatic region adjacent a condensation side of a thermal management component may be similar or close to the surface energy of the wick at the condensation side of the thermal management component. In examples, the surface energy of a wick may be affected by surface treatment such as oxidation or silane treatment. In examples, a wick may extend at least along an internal portion of a thermal management component. In examples, a wick may extend the full or almost the full internal length of thermal management component. In examples, a wick may extend through one or more bellows. In examples, a wick may include a mesh, fiber, a corrugated surface, or any combination thereof.

In examples, a mesh wick may include a metal, carbon, polymer, or any combination thereof. In examples, a mesh wick may include a metal such as copper, copper alloy, titanium, titanium alloy, aluminum, aluminum alloy, or any combination thereof. In examples, a mesh wick may be sintered or unsintered. In examples, a mesh wick may include a composite structure. In examples, a mesh wick may include woven wires such as a mesh, metal foams, sintered powders, one or more coatings, or any combinations thereof. In examples, a coating may be Al2O3/SiO2 bilayer. In examples, a mesh wick may include copper or copper alloy, nylon, or any combination thereof.

In examples, a mesh wick may be bonded to an internal surface of a thermal management component. In examples, a mesh wick may be bonded to an internal surface of a thermal management component by spot welding, brazing, thermal compression, thermosonically, or like process.

Illustrated in FIG. 2A, heat pipe 202 may include a wick 218. In examples, the wick 218 may include a fine copper and/or titanium mesh 220, thermosonically boded to an internal surface of heat pipe 202. In examples, as shown, wick 218 and/or 220 may extend through bellows 204.

In examples, bellows 204 may be configured to allow transfer of working fluid from one side of heat pipe 202 to a second side of heat pipe 202. In examples, bellows 204 may be configured to further promote capillary action inside heat pipe 202. In examples, at least a portion of an internal surface of bellows 204 that lies under a mesh wick 220 may be treated to promote capillary action. In examples, at least a portion of an internal surface of bellows 204 may be treated with a surface chemical treatment and/or a heat treatment.

In examples, above wick 218, and above a fiber wick 232 if present as described later, heat pipe 202 may include a vapor space 222. In examples, vapor space 222 may be configured to allow transfer of vapor from a first side of heat pipe 202 to a second side of heat pipe 202. For example, vapor may travel from evaporation side 208 to condensation side 210. In examples, vapor space 222 may extend along the full length of heat pipe 202. In examples, a bellows 204 may be configured to allow a vapor space 222 to extend therethrough.

In examples, one or more spacers 224 may be provided inside heat pipe 202 to maintain a proper distance between internal surfaces of heat pipe 202 and ensure that vapor space 222 is not occluded. In examples, one or more spacers 224 may be included in bellows 204. In examples, one or more spacers 224 may be included in bellows 204 to prevent collapse or pinching of the internal surfaces during bending and/or flexing of the bellows 204. In examples, as shown in FIG. 2A, spacer 224 may include a spring 226. Other types of spacers may also be used. For examples, spacer 224 may include a sphere, a hollow sphere with ingress and egress features, a stud, a ring, a mesh such as a mesh ball or mesh cylinder, or any like structure that can provide structural support sufficient to prevent or minimize restriction of an internal area of heat pipe 202, especially at bellows 204 when the bellows 204 is bent or flexed. In examples, a spacer 224 may include a hollow region. In examples, a spacer 224 may be provided above a wick that is provided inside bellows 204. In examples, a spacer 224 inside a bellows 204 may include a hydrophobic surface. In examples, a spacer 224 inside a bellows 204 may be configured to allow fluid flow or not block fluid flow through the bellows 204 and/or configured to allow or not prevent the insertion of a wick or other desired structure.

FIG. 2B illustrates another example of a thermal system 200. This example is similar to what has been described in FIG. 2A except for the wick 218. In the example of FIG. 2B, wick 218 is provided as a corrugated surface 228 at a portion of an internal surface of heat pipe 202. As shown, one or more capillary features 230 such as corrugations may be etched along at least a portion of an internal surface of heat pipe 202. In examples, the corrugated surface of heat pipe 202 may be a bottom internal surface. In examples, the capillary features 230 may be provided by chemical etching, laser ablation, or any other method. In examples, an etch chemistry may include a photolithography etch process using a caustic solution to achieve microetching. In examples, the caustic solution may include hydrofluoric acid, potassium hydroxide, or the like. In examples, a laser ablation may be carried out using a fiber laser that may be an ultrafast laser, a very fast laser, or a fast laser. In examples, an ultrafast laser is a laser with a pulse in the femtosecond range, a very fast laser is a laser with a pulse in the picosecond range, and a fast laser is a laser with a pulse in the nanosecond range. In examples, laser ablation may be carried out as described in co-pending U.S. application Ser. No. 17/559,949, filed on Dec. 22, 2021, which is incorporated herein by reference in its entirety.

In examples, capillary features 230 and/or corrugations may be of any desired size. In examples, capillary features 230 may have a width and depth of about 40 μm to about 100 μm. In examples, the capillary features 230 may have a width and depth of about 50 μm. In examples, one or more surface treatments may be performed to the etched and/or ablated surface to affect the surface energy and enhance hydrophilic characteristics of the corrugated surface 228 at least at the evaporation side of the heat pipe 202.

In examples, not shown, the wick 218 in a heat pipe 202 may be provided as a combination of mesh as described with referenced to FIG. 2A and corrugated surface as described with reference to FIG. 2B. For example, a mesh may be bonded over a corrugated surface to form a dual wick structure to enhance capillary action within heat pipe 202. In examples, wick 218 may include a fiber instead of a mesh over one or more capillary features 230.

In examples, to promote capillary action through a bellows 204 in the thermal systems 200 of FIGS. 2A and/or 2B, a fiber wick 232 may be included at least through the internal length of bellows 204. In examples, fiber wick 232 provided in the internal volume of bellows 204 may be in addition to and/or in place of mesh wick 220. In examples, fiber wick 232 may extend through bellows 204 in place of mesh wick 220. In examples, fiber wick 232 extends only through the bellows 204. In examples, fiber wick 232 extends beyond bellows 204. In examples, fiber wick 232 extends through at least a portion of condenser side of the thermal system 202.

In examples, fiber wick 232 may overlay mesh wick 220. In examples, fiber wick 232 may underlay mesh wick 220. In examples, fiber wick 232 may be connected to mesh wick 220. In examples, wick 218 extending through bellows 204 may include a mesh wick 220 as previously described and fiber wick 232 includes a fiber as described herein. In examples, where mesh wick 220 is not present and wick 218 includes a corrugated surface 228, with capillary features 230, as illustrated in FIG. 2B, fibers of fiber wick 232 may extend over at least a portion of and/or be bonded to one or more portions of the corrugated surface 228 and/or capillary features 230.

In examples, fiber wick 232 may include a material that exhibit hydrophilicity. In examples, fiber wick 232 may include a material that has a water contact angle of less than 45°. In examples, fiber wick 232 may include a material that has a contact angle of less than 40°, less than 35°, less than 30°, less than 25°, less than 20°, less than 15°, and at least 5°. In examples, fiber wick 232 may include fibers having a diameter ranging from about 20 μm to about 80 μm. In examples, fiber wick 232 may include fibers having a diameter in the range of about 25 μm to 75 μm.

In examples, fiber wick 232 may include a treated polymer material, a metal, and/or glass. In examples, fiber wick 232 may include polyethylene terephthalate (PET). Other polymers may also be used for fiber wick 232. In examples, fiber wick 232 may include glass fiber. In examples, fiber wick 232 may include metal fiber. In examples, fiber wick 232 may include a functionalized material, for example a functionalized polymer and/or functionalized metal. In examples, functionalization of a polymer fiber may be effectuated via a plasma process. In examples, functionalization of a metal fiber may be effectuated via a heat treatment. In examples, fiber wick 232 may include metal and polymer materials. In examples, fiber wick 232 may include polymer fibers coated with a metal. In examples, fiber wick 232 may include in the fiber and/or as a coating over the fiber a metal such as copper, nickel, titanium, aluminum, or any combination or alloy thereof. In examples, the metal included in the fibers of a fiber wick 232 may be the same as the metal used for mesh wick 220 and/or heat pipe 202. In examples, a metal fiber and/or metal coating over polymer fibers of fiber wick 232 may extend over at least a portion of mesh wick 220, corrugated surface 228, one or more capillary features 230, and/or a portion of wick 218.

In examples, fiber wick 232 may be thermally bonded to the mesh wick 220, a portion of corrugated surface 228, one or more capillary features 230, a portion of wick 218, one or more portions of heat pipe 202, or any combination thereof. In examples, the metal in fiber wick 232 and/or metal coating over fibers of fiber wick 232 may be used to thermally bond the fiber wick 232 to the mesh wick 220, a portion of corrugated surface 228, one or more capillary features 230, a portion of wick 218, one or more portions of heat pipe 202, or any combination thereof. In examples, the connection may be made by welding. In examples, the connection may be by thermosonic bonding, laser welding, brazing, or any other suitable thermal process. In examples, the fibers of fiber wick 232 may be bonded over mesh wick 220, portions of corrugated surface 228, one or more capillary features 230, portions of wick 218, a portion of heat pipe 202, or any combination thereof. In examples, the fibers of fiber wick 232 may bridge two portions of mesh wick 220, portions of corrugated surface 228, one or more capillary features 230, and/or portions of wick 218. Any combinations of these arrangements may be implemented.

In examples, an electronic device may include a thermal system 200 as illustrated in FIGS. 2A and 2B. In examples, the thermal system 200 as illustrated in FIGS. 2A and 2B may extend within an electronic device from a first location where heat is mostly generated, such as for example, proximate to and/or thermally coupled to one or more electronic components 234, to a second location of the electronic device where heat is not generated and/or less heat is generated than the first location. In examples, the electronic device may include a curved portion and/or a mechanical articulation such as one provided by a coupler between the first location and the second location. In examples, a bellows 204 of thermal system 200 may be arranged to correspond to the curved portion and/or mechanical articulation portion of the electronic device. In this manner, the thermal system 200 may be arranged so that an evaporation side of heat pipe 202 may receive heat from the first location of the electronic device and spread it via the condensation end at the second location of the electronic device even though a curved portion and/or mechanical articulation stands between the two locations. In examples, the bellows 204 allows for the bending and/or flexing of thermal system 200 to accommodate the curved portion and/or mechanical articulation of the electronic device with minimal to no impedance imposed on the heat spreading functionality.

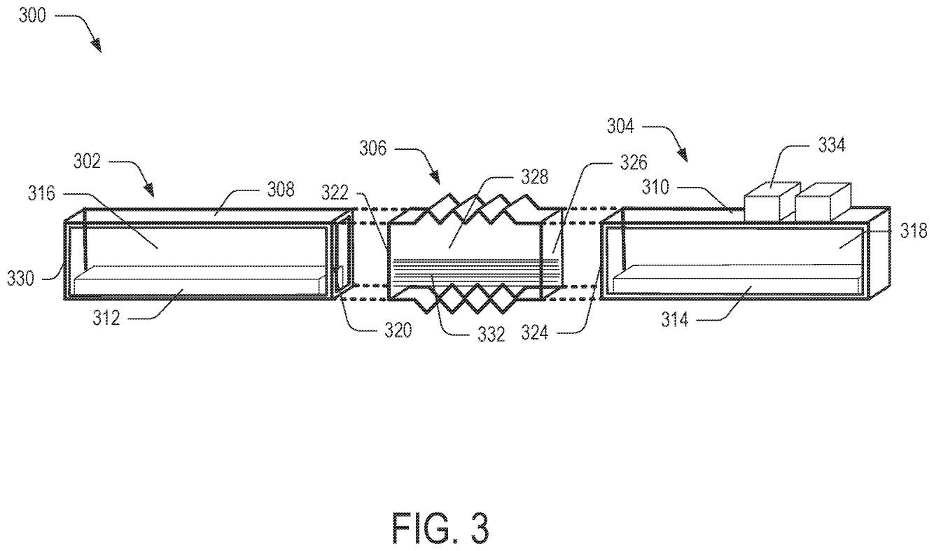

FIG. 3 illustrates an example thermal system in which a bellows is connected to rather than being integrated into a thermal management component. In examples, a connecting bellows may be a modular bellows that may be used with and/or connected to one or more types of thermal management components. In examples, a connecting bellows may be used as a connection between two thermal management components. In examples, as illustrated, a thermal system 300 may include at least a first heat pipe 302 and a second heat pipe 304 interconnected by a connecting bellows 306.

In examples, first heat pipe 302 and second heat pipe 304 may have similar or different structures. In examples, first heat pipe 302 and second heat pipe 304 may each include a rigid structure. In examples, first heat pipe 302 and second heat pipe 304 each independently includes at least an outer shell 308 and 310, a wick 312 and 314, and a vapor space 316 and 318. In examples each of the first heat pipe 302 and second heat pipe 304 may include at least one mating end 320 and 324 configured to engage a respective mating end 322 and 326 connecting bellows 306.

In examples, a connecting bellows 306 may be connected to one end of the first heat pipe 302 and to one end of the second heat pipe 304. In examples, a connecting bellows 306 may include a first mating end 322 and a second mating end 326. In examples, first mating end 322 and second mating end 326 may be opposite each other. In examples, the engagement between a mating end of connecting bellows 306 and a mating end of a heat pipe may be effectuated by mechanical boding, thermal boding, adhesive, or any combination thereof. In examples, a connecting bellows 306 may be configured to include one or more mating ends designed to mate with predetermined types of mating ends of a heat pipe. In examples, a connecting bellows 306 may have a first and second mating ends configured to have the same or different profile and/or design. In examples, a connecting bellows 306 may be configured to include one or more universal mating ends designed to mate any type of mating ends of a heat pipe.

In examples, mechanical bonding may be effectuated, for example, by one or more fasteners such as screws, bolts, clamps, or similar device. In examples, a mechanical bonding may be effectuated by bonding a mating end of a heat pipe to a mating end of the bellows, for example, the mating end of a heat pipe may screw into a mating end of the bellows or a mating end of the bellows may screw into a mating end of a heat pipe. In examples, thermal bonding may be effectuated by welding, brazing, thermosonic bonding, laser bonding or any other suitable process. In examples, any adhesive suitable to bond the materials of the heat pipe and bellows may be employed, including polymer adhesives, resins, or any like adhesive. In examples, bonding of a bellows mating end to a heat pipe mating end may form a hermetic seal.

In examples, a connecting bellows 306 may include metal folds, ridges, or a pleated pattern as previously described with reference to bellows 204.

In examples, a connecting bellows 306 may be formed of the same or different material as the outer shell 308 of the first heat pipe 302 and/or outer shell 310 of the second heat pipe 304. In examples, the outer shell 308 of the first heat pipe 302 may include the same or different material as the outer shell 310 of second heat pipe 304. In examples, connecting bellows 306 may include copper, nickel, titanium, or any alloy or combination thereof. In examples, connecting bellows 306 includes nickel. In examples, an advantage of using nickel for bellows 306, and/or similar outer shell material for the first heat pipe 302, second heat pipe 304, and connecting bellows 306 is that it may provide for improved thermal boding. In examples, at least the mating end of a connecting bellows 306 and the mating end of a heat pipe may include at least one common material. In examples, at least the mating end of a connecting bellows 306 may include nickel. In examples, connecting bellows 306 may consist of metal.

In examples, connecting bellows 306 may be welded on one side to mating end 320 of first heat pipe 302 and on a second side, opposite the first side, to mating end 324 of second heat pipe 304. In examples, the bond between connecting bellows 306 and a heat pipe forms a hermetic seal.

In examples, once bonded to the first heat pipe 302 and second heat pipe 304, connecting bellows 306 may provide fluid communication between the first heat pipe 302 and the second heat pipe 304. In examples, connecting bellows 306 may include a hollow internal volume or space 328 through which fluid may flow. In examples, hollow internal volume or space 328 may extend within connecting bellows 306 from first mating end 322 of connecting bellows 306 to second mating end 326 of connecting bellows 306. In examples, the hollow internal volume or space 328 may allow for working fluid and/or vapor to flow through. In examples, a hollow internal volume or space 328 of a connecting bellows 306 may be configured to house one or more wicks. In examples, wick 312 of the first heat pipe 302 and/or wick 314 of the second heat pipe 304 may be configured to extend at least into a portion of internal volume or space 328 of connecting bellows 306. In examples, wick 312 and/or wick 314 may be a contiguous wick that is configured to extend from the first heat pipe 302 to the second heat pipe 304 passing through internal volume or space 328 of connecting bellows 306.

In examples, a contiguous wick formed of wicks 312 and/or 314 may be inserted inside first heat pipe 302, second heat pipe 304, and connecting bellows 306 during manufacturing after connecting bellows 306 is bonded to the first heat pipe 302 and second heat pipe 304. For example, first heat pipe 302 may be configured to have an open end 330, at an opposite side from mating end 320. After connecting bellows 306 is bonded to first heat pipe 302 and second heat pipe 304, a wick mesh and/or fiber wick may be inserted through open end 330 of the first heat pipe. In examples, a fiber wick 332 as described later may be provided in connecting bellows 306 prior to bonding connecting bellows 306 to first and second heat pipes 302 and 304. The open end 330 may then be sealed and a vacuum created inside the first heat pipe 302, second heat pipe 304, and connecting bellows 306. A working fluid may be inserted via an orifice provided, for example, at sealed end 330 or at an opposite end of the thermal system 300. In examples, open end 330 may be provided in the second heat pipe 304 instead of the first heat pipe 302. In examples, an open end 330 may be provided at both the first heat pipe 302 and second heat pipe 304, in which case both open ends would then be sealed prior forming a vacuum inside the bonded structure.

Although not shown, a connecting bellows 306 may include one or more spacers as previously described with reference to FIGS. 2A and 2B. As previously discussed, one or more spacers may be configured to prevent collapsing of an interior wall of connecting bellows 306 and/or pinching when the thermal system 300 is bent at connecting bellows 306. As also previously discussed, a spacer may be any suitable structure such as a stud, a mesh, a sphere, a ring, a spring, or any like device. In examples, a spacer may be provided above a wick that is provided inside connecting bellows 306. In examples, a spacer that is provided in a connecting bellows 306 may include a hydrophobic surface. In examples, a spacer provided in connecting bellows 306 may be configured to allow flow or not block flow of fluid through connecting bellows 306 and/or configured to allow or not prevent insertion of a wick through at least a portion of internal volume or space 328 of connecting bellows 306. In examples, a spacer may be provided above a wick that is provided inside connecting bellows 306.

In examples, connecting bellows 306 may include a fiber wick 332 as similarly described earlier with reference to FIGS. 2A and 2B. In examples, a fiber wick 332 may promote capillary action through connecting bellows 306 in the thermal systems 300. A fiber wick 332 may be included at least through the length of the hollow internal volume or space 328 of connecting bellows 306. In examples, fiber wick 332 extends only through connecting bellows 306. In examples, fiber wick 332 extends beyond connecting bellows 306. In examples, fiber wick 332 extends through at least a portion of the first heat pipe 302, second heat pipe 304, or both, in addition to extending through connecting bellows 306. In examples, fiber wick 332 is provided through connecting bellows 306 and through at least a portion of the condensation side of thermal system 300.

In examples, fiber wick 332 provided in the hollow internal volume or space 328 of connecting bellows 306 may be in addition to and/or in place of wicks 312 and/or 314. In examples, fiber wick 332 may extend through connecting bellows 306 in place of wicks 312 and/or 314. In examples, fiber wick 332 may overlay wicks 312 and/or 314. In examples, fiber wick 332 may underlay wicks 312 and/or 314. In examples, fiber wick 332 may be connected to wicks 312 and/or 314. In examples, wicks 312 and/or 314 extending through connecting bellows 306 may include a mesh wick as previously described and fiber wick 332. In examples, where wick 312 and/or 314 extending through first heat pipe 302 and/or second heat pipe 304 include a corrugated surface with capillary features, fibers of fiber wick 332 may extend over at least a portion of and/or be bonded to one or more portions of the corrugated surface and/or capillary features.

In examples, fiber wick 332 may include a material that exhibit super-hydrophilicity. In examples, fiber wick 332 may include a material that has a water contact angle of less than 45°. In examples, fiber wick 332 may include a material that has a contact angle of less than 40°, less than 35°, less than 30°, less than 25°, less than 20°, less than 15°, and at least 5°. In examples, fiber wick 332 may include fibers having a diameter ranging from about 20 μm to about 80 μm. In examples, fiber wick 332 may include fibers having a diameter in the range of about 25 μm to 75 μm.

In examples, fiber wick 332 may include a treated polymer material, a metal, and/or glass. In examples, fiber wick 332 may include polyethylene terephthalate (PET). Other polymers may also be used for fiber wick 332. In examples, fiber wick 332 may include glass fiber. In examples, fiber wick 332 may include metal fiber. In examples, fiber wick 332 may include a functionalized material, for example a functionalized polymer and/or functionalized metal. In examples, functionalization of a polymer fiber may be effectuated via a plasma process. In examples, functionalization of a metal fiber may be effectuated via a heat treatment. In examples, fiber wick 332 may include metal and polymer materials. In examples, fiber wick 332 may include polymer fibers coated with a metal. In examples, fiber wick 332 may include in the fiber and/or as a coating over the fiber a metal such as copper, nickel, titanium, aluminum, or any combination or alloy thereof. In examples, the metal included in the fibers of a fiber wick 332 may be the same as the metal used for a mesh or fibers used for wicks 312 and/or 314. In examples, one or more fibers of fiber wick 332 and/or a metal coating over fibers of fiber wick 332 may extend over at least a portion of a mesh or fibers used for wicks 312 and/or 314, a corrugated surface and/or one or more capillary features in first and second heat pipes 302 and 304.

In examples, fiber wick 332 may be thermally bonded to the mesh or fiber of wicks 312 and/or 314, a portion of corrugated surface and/or one or more capillary features of one or more portions of first and second heat pipes 302 and 304, or any combination thereof. In examples, the metal in fiber wick 332 and/or metal coating over fibers of fiber wick 332 may be used to thermally bond the fiber wick 332 to the mesh or fiber of wicks 312 and/or 314, a portion of corrugated surface and/or one or more capillary features of one or more portions of first and second heat pipes 302 and 304, or any combination thereof. In examples, the connection may be made by welding. In examples, the connection may be by thermosonic bonding, laser welding, brazing, or any other suitable thermal process. In examples, the fibers of fiber wick 332 may be bonded over mesh and/or fiber of wick 312 and/or 314, portions of corrugated surface and/or one or more capillary features of first and second heat pipes 302 and 304, or any combination thereof. In examples, the fibers of fiber wick 332 may bridge wicks 312 and 314. For example, fibers of fiber wick 332 may bridge respective mesh or fibers of wicks 312 and 314 portions, and/or bridge the corrugated surface and/or one or more capillary features provided in the first and second heat pipes 302 and 304. Any combinations of these arrangements may be implemented.

In examples, the thermal system 300 may employ the first heat pipe 302 as an evaporation side and the second heat pipe 304 as a condensation side. In examples, an electronic device may be equipped with a thermal system 300 and may include a heat pipe at a first location where heat is mostly generated, such as for example, proximate to and/or thermally coupled to one or more electronic components 334. In examples, a heat pipe 302 of a thermal system 300 may be provided at a second location of the electronic device where heat is not generated and/or less heat is generated than the first location. In examples, the electronic device may include a curved portion and/or a mechanical articulation such as one provided by a coupler between the first location and the second location. In examples, connecting bellows 306 of thermal system 300 may be arranged to correspond to the curved portion and/or mechanical articulation portion of the electronic device to accommodate the curved portion and/or mechanical articulation of the electronic device with minimal to no impedance imposed on the heat spreading functionality.

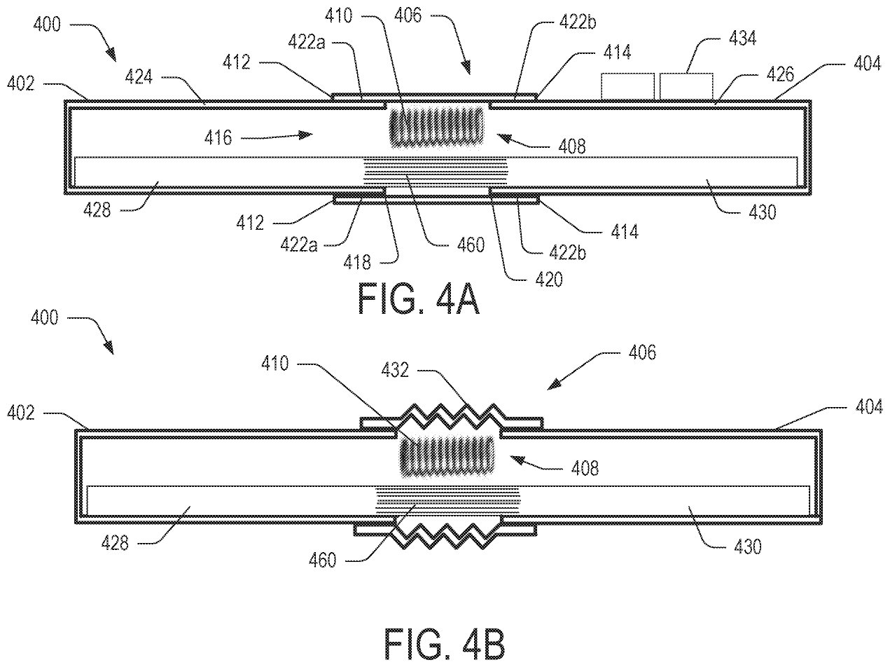

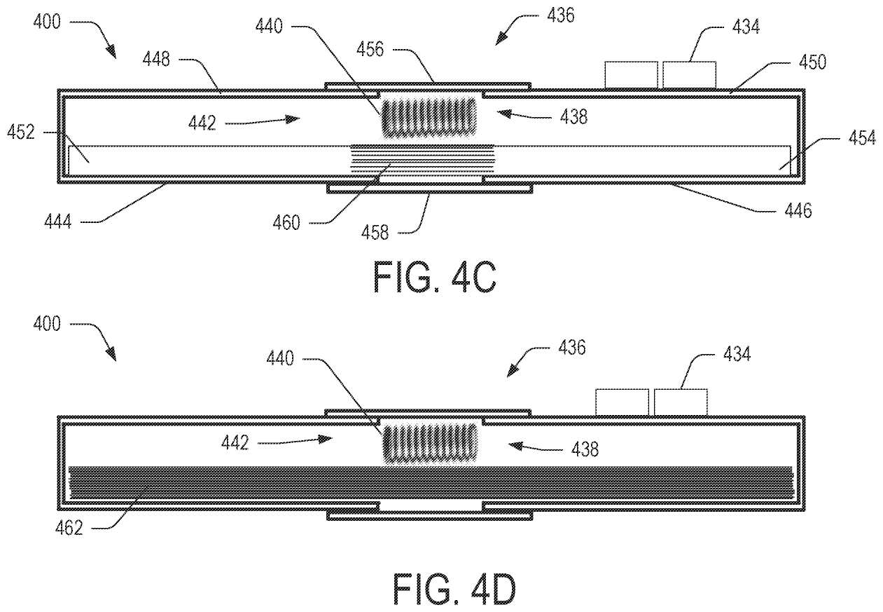

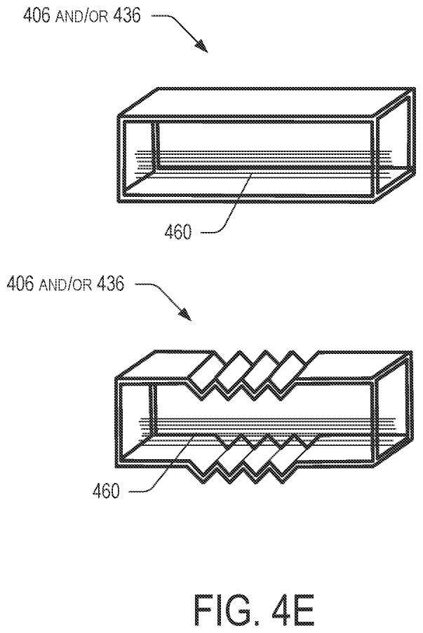

FIGS. 4A-4D illustrate examples of thermal systems in which a flexible portion is formed of a polymer material. In examples, use of a polymer material may enhance flexibility of the bellows. In examples, a polymer material may be used to form a hollow connector between two thermal management components. In examples, the hollow connector may be formed to include pleats or folds such as a bellows as previously described. In examples, the hollow connector may have flat surfaces. In examples, a hollow connector may be formed as a single integral body, for example by extrusion or molding. In examples, a hollow connector may be formed by bonding two or more sheets of polymer material together.

In examples, as illustrated, a thermal system 400 may include at least a first heat pipe 402 and a second heat pipe 404 interconnected by a polymer hollow connector 406. In examples, a hollow connector 406 may be connected to one end of the first heat pipe 402 and to one end of the second heat pipe 404. In examples, the first heat pipe 402 and second heat pipe 404 may each include a rigid structure.

FIG. 4A illustrates an example of thermal system 400 in which a hollow connector 406 include a polypropylene, polyethylene terephthalate (PET) or a combination of both. In examples, polypropylene and PET can enhance the bendability of hollow connector 406 due to its flexible nature. In examples, hollow connector 406 includes a high molecular weight polymer that is thermally conductive. In examples, hollow connector 406 may include high molecular PET. In examples, hollow connector 406 may include PET of a molecular weight that is at least about 5,000,000 gr/mol. In examples, hollow connector 406 includes a material having a thermal conductivity of 25 W/mK or higher. In examples, the hollow connector 406 may include a material having a thermal conductivity within the range of 25 to 40 W/mK, for example, 25 to 35 W/mK.

In examples, as illustrated, hollow connector 406 may have a flat profile instead of pleats. Alternatively, in examples, a hollow connector 406 even if formed of flexible polypropylene or PET, may also be formed as a bellows and include ridges, folds, or pleats 432 as previously described as, for example, shown in FIG. 4B.

In examples, a hollow connector 406 may include one or more spacers 408. In examples, a spacer 408 may include any suitable structure as previously described such as a stud, a mesh, a sphere, a ring, a spring, or any like device.

Illustrated in FIG. 4A, a spacer 408 is shown as a spring 410. In examples, one or more spacers 408 may prevent or minimize the collapse of hollow connector 406 when it is bent so that fluid flow through hollow connector 406 is not blocked. In examples, a spacer 408 may include a hydrophobic surface. In examples, a spacer 408 may be configured to allow fluid flow or not block fluid flow through hollow connector 406 and/or configured to allow or not prevent the insertion of a wick or other desired structure. In examples, a spacer 408 may be provided above a wick that is provided inside hollow connector 406.

In examples, hollow connector 406 may include a first mating end 412 and second mating end 414. In examples, first mating end 412 and second mating end 414 may be opposite each other. In examples, a hollow internal volume or space 416 may extend within hollow connector 406 from first mating end 412 to second mating end 414. In examples, first and second mating ends 412 and 414 may be configured to include the same or different design and/or profile. In examples, first and second mating ends 412 and 414 may each be configured to engage a corresponding mating end of a heat pipe. For example, as illustrated, a first mating end 412 of hollow connector 406 may be configured to engage a mating end 418 of first heat pipe 402. Also, in examples, as shown, a second mating end 414 of hollow connector 406 may be configured to engage a mating end 420 of second heat pipe 404.

In examples, bonding of a mating end of hollow connector 406 to a mating end of a heat pipe can form a hermetic seal. In examples, bonding of a hollow connector 406 to a heat pipe may include fitting or overlapping at least a portion of the heat pipe inside or with at least a portion of hollow connector 406 or fitting at least a portion of hollow connector 406 inside at least a portion of the heat pipe. In examples, when bonded together, an area 422 (e.g., 422a and 422b) may be present where at least a portion of hollow connector 406 and a portion of a heat pipe overlap. In examples, area 422 may extend along a full or a portion of a perimeter of the heat pipe, hollow connector 406, or both.

In examples, the bonding between hollow connector 406 and a heat pipe may be accomplished via mechanical bonding, thermal bonding, adhesive, or any combination thereof. In examples, mechanical bonding may be effectuated, for example, by one or more fasteners such as screws, bolts, clamps, or similar device. In examples, thermal bonding may be effectuated by thermal process such as thermosonic bonding, laser bonding or any other suitable process. In examples, any adhesive suitable to bond the materials of the heat pipe and bellows may be employed, including polymer adhesives, resins, or any like adhesive. In examples, at least a portion of hollow connector 406 along at least a portion of area 422 may be lined or plated with one or more metals. In examples, the metals provided at a portion of hollow connector 406 along at least a portion of area 422 may be the same or different metal that is used for an outer shell of a heat pipe to be bonded to hollow connector 406. In examples, having the same metal on hollow connector 406 and the outer shell of heat pipe to be bonded to hollow connector 406 may allow for welding or other thermal process that may result in a stronger bond.

In examples, the first heat pipe 402 and the second heat pipe 404 may be the same or different. In examples, each of first heat pipe 402 and second heat pipe 404 may include an outer shell 424 and 426 respectively and a wick 428 and 430 respectively. In examples, the outer shell and the wick may be materials and be formed as previously described. In examples, each heat pipe outer shell 424 and 426 may independently include copper, copper alloy, titanium, titanium alloy, aluminum, aluminum alloy, or any combination thereof. In examples, each heat pipe wick 428 and 430 may independently include a mesh, a corrugated surface with one or more capillary features, a fiber, or a combination thereof. In examples, the wick of a heat pipe may be more hydrophilic in an evaporation side than in the condensation side. In examples, the surface energy of the wick along an adiabatic region may gradually change from the evaporation side to the condensation side. In example, a wick may extend through hollow connector 406. For example, a mesh or fiber wick may extend through or extend at least into a portion of an internal hollow space 416 of hollow connector 406. In examples, at least a portion of each of wick 428 and wick 430 may form a contiguous wick that extends from at least a portion of the first heat pipe 402 to at least a portion of the second heat pipe 404, and through hollow connector 406. Although not shown, the thermal system 400 may include a working fluid as previously described. In examples, the working fluid may be water.

In examples, one or more electronic components 434 may be thermally coupled to one or more of the first heat pipe 402 and second heat pipe 404. In examples, one heat pipe may be configured to function as an evaporation side of the thermal system 400 and be thermally coupled to heat generating electronic components 434 and the other heat pipe may be configured to function as the condensation side of the thermal system 400. In examples, hollow connector 406 may be provided at an adiabatic region of thermal system 400. In this manner, thermal system 400 may provide an end-to-end solution. In examples, the thermal system 400 as illustrated may be configured to spread heat generated in one location of an electronic device to one or more other locations of the electronic device.

FIG. 4C illustrates a similar thermal system 400 as described with reference to FIG. 4A except that hollow connector 406 is replaced with hollow connector 436. In examples, hollow connector 436 differs from hollow connector 406 in that it may include a polyimide flex material instead of or in addition to polypropylene.

In examples, polyimide flex material may include any suitable polyimide. In examples, the polyimide flex material of hollow connector 436 may include Kapton® (poly-oxydiphenylene-pyromellitimide), made by DuPont Corporation. In examples, hollow connector 436 may be free of metal. In examples, absence of metal in hollow connector 436 may provide for enhanced flexibility of the hollow connector 436. In examples, hollow connector 436 may include a flexible printed circuit. In examples, hollow connector 436 may be lamination and include one or more circuits thereon. For example, hollow connector 436 may include a resin coated copper foil.

In examples, hollow connector 436 may include one or more spacers 438 similar to the previously described spacers 408. In examples, a spacer 408 may be configured to ensure that the hollow connector 436 does not collapse or pinch so that fluid flow through the hollow connector 436 is maintained and not blocked. As illustrated in FIG. 4C, a spacer 438 may include a spring 440. In examples, a spacer 438 may be any suitable structure such as a stud, a mesh, a sphere, a ring, a spring, or any like device. In examples, a spacer 438 may include a hydrophobic surface. In examples, a spacer 438 may be configured to allow flow or not block flow of fluid through hollow connector 436 and/or configured to allow or not prevent insertion of a wick through at least a portion of an internal volume or space 442 of hollow connector 436. In examples, internal volume or space 442 may be located within hollow connector 436 and extending from one mating end to the other as previously described with reference to FIG. 4A. In examples, a spacer 438 may be provided above a wick that is provided inside hollow connector 436.

In examples, a first heat pipe 444 and a second heat pipe 446 connected to hollow connector 436 may each include an outer shell 448 and 450, and optionally a wick 452 and 454. In examples, outer shell 448 and 450 may each independently include a high thermally conductive material as previously described. In examples, outer shell 448 and/or outer shell 450 may include oxygen free copper (OFC). In examples, the OFC may include large grains that are directional and configured for cyclical fatigue.

In examples, hollow connector 436 may include two or more plates bonded together. As illustrated, hollow connector 436 may include a first plate 456 and a second plate 458. In examples, when bonded together first plate 456 and second plate 458 may extend along the full perimeter of a heat pipe connected thereto. In examples, first plate 456 and second plate 458 may be bonded along the perimeter of an end of first heat pipe 444 and along the perimeter of an end of second heat pipe 446. In examples, the bond creates a hermetic seal. In examples, the bond may be made by seam welding or brazing. In examples, first plate 456 and second plate 458 may include a metal, such as copper, nickel, alloys thereof, or a combination thereof, that can be welded to outer shell of the first and second heat pipes. For example, first plate 456 and second plate 458 may be at least partially laminated with a metal. In examples, the first plate 456 and/or the second plate 458 may include the same metal as the outer shell of the first heat pipe 444 and second heat pipe 446 at the respective mating ends. The same metal may be provided at each mating end or different metals may be provided at different mating ends. In examples, providing metal at the mating end of first plate 456 and second plate 458 may allow for a stronger bond between the plate and the heat pipe.

In examples, first heat pipe 444 and second heat pipe 446 may include a wick 452 and 454. In examples, a contiguous wick may extend from one heat pipe to the other. In examples, each wick 452 and 454 are separate wicks. In examples, a wick can be a mesh, a fiber, a corrugated surface with capillary features or any combination thereof as previously described. Although illustrated with a polygonal cross-section in the width direction, the hollow connector may alternatively be rounded. As shown, and as previously described, in examples, the hollow connector 436 may have a planar profile or a pleated profile.

In examples, hollow connector 406 or 436 may further include a fiber wick 460 in addition to or in place of wicks 428 and 430 as previously described with reference to FIGS. 2A, 2B, and 3. In examples, a fiber wick 460 may promote capillary action through hollow connector 406 or 436 in the thermal systems 400. A fiber wick 460 may be included at least through the length of the hollow internal volume or space 416 or 442 of hollow connector 406 or 436. In examples, fiber wick 460 extends only through hollow connector 406 or 436. In examples, fiber wick 460 extends beyond hollow connector 406 or 436. In examples, fiber wick 460 extends through at least a portion of the first heat pipe, second heat pipe, or both, in addition to extending through hollow connector 406 or 436. In examples, fiber wick 460 is provided through hollow connector 406 or 436 and through at least a portion of the condensation side of thermal system 400.

In examples, fiber wick 460 provided in the hollow internal volume or space 416 or 442 of hollow connector 406 or 436 may be in addition to and/or in place of wicks 428 and 430 or 452 and 454. In examples, fiber wick 460 may extend through hollow connector 406 or 436 in place of wicks 428 and/or 430, or 452 and/or 454. In examples, fiber wick 460 may overlay wicks 428 and/or 430, or 452 and/or 454. In examples, fiber wick 460 may underlay wicks 428 and/or 430, or 452 and/or 454. In examples, fiber wick 460 may be connected to wicks 428 and/or 430, or 452 and/or 454. In examples, wicks 428 and/or 430, or 452 and/or 454 extending through hollow connector 406 or 436 may include a mesh wick as previously described and fiber wick 460. In examples, where wick 428 and/or 430, or 452 and/or 454 extending through first heat pipe 402 or 444 and/or second heat pipe 404 or 446 include a corrugated surface with capillary features, fibers of fiber wick 460 may extend over at least a portion of and/or be bonded to one or more portions of the corrugated surface and/or capillary features.

In examples, fiber wick 460 may include a material that exhibit super-hydrophilicity. In examples, fiber wick 460 may include a material that has a water contact angle of less than 45°. In examples, fiber wick 460 may include a material that has a contact angle of less than 40°, less than 35°, less than 30°, less than 25°, less than 20°, less than 15°, and at least 5°. In examples, fiber wick 460 may include fibers having a diameter ranging from about 20 μm to about 80 μm. In examples, fiber wick 460 may include fibers having a diameter in the range of about 25 μm to 75 μm.

In examples, fiber wick 460 may include a treated polymer material, a metal, and/or glass. In examples, fiber wick 460 may include polyethylene terephthalate (PET). Other polymers may also be used for fiber wick 460. In examples, fiber wick 460 may include glass fiber. In examples, fiber wick 460 may include metal fiber. In examples, fiber wick 460 may include a functionalized material, for example a functionalized polymer and/or functionalized metal. In examples, functionalization of a polymer fiber may be effectuated via a plasma process. In examples, functionalization of a metal fiber may be effectuated via a heat treatment. In examples, fiber wick 460 may include metal and polymer materials. In examples, fiber wick 460 may include polymer fibers coated with a metal. In examples, fiber wick 460 may include in the fiber and/or as a coating over the fiber a metal such as copper, nickel, titanium, aluminum, or any combination or alloy thereof. In examples, the metal included in the fibers of a fiber wick 460 may be the same as the metal used for a mesh or fibers used for wicks 428 and/or 430, or 452 and/or 454. In examples, a fibers of fiber wick 460 and/or a metal coating over fibers of fiber wick 460 may extend over at least a portion of a mesh or fibers used for wicks 428 and/or 430, or 452 and/or 454, a corrugated surface and/or one or more capillary features in first and second heat pipes 402 and 404 or 444 and 446.

In examples, fiber wick 460 may be thermally bonded to the mesh or fiber of wicks 428 and/or 430, or 452 and/or 454, a portion of corrugated surface and/or one or more capillary features of one or more portions of first and second heat pipes 402 and 404 or 444 and 446, or any combination thereof. In examples, the metal in fiber wick 460 and/or metal coating over fibers of fiber wick 460 may be used to thermally bond the fiber wick 460 to the mesh or fiber of wicks 428 and/or 430, or 452 and/or 454, a portion of corrugated surface and/or one or more capillary features of one or more portions of first and second heat pipes 402 and 404 or 444 and 446, or any combination thereof. In examples, the connection may be made by welding. In examples, the connection may be by thermosonic bonding, laser welding, brazing, or any other suitable thermal process. In examples, the fibers of fiber wick 460 may be bonded over mesh and/or fiber of wick 428 and/or 430, or 452 and/or 454, portions of corrugated surface and/or one or more capillary features of first and second heat pipes, or any combination thereof. In examples, the fibers of fiber wick 460 may bridge wicks 428 and 430, or 452 and 454. For example, fibers of fiber wick 460 may bridge respective mesh or fibers of wicks 428 and 430, or 452 and 454 portions, and/or bridge the corrugated surface and/or one or more capillary features provided in the first and second heat pipes. Any combinations of these arrangements may be implemented.

FIG. 4D illustrates a similar thermal system 400 as described with reference to FIG. 4C except that the thermal system 400 includes a contiguous fiber wick 462 that may extend from at least a portion of the first heat pipe 444 to at least a portion of the second heat pipe 446. In examples, fiber wick 462 extends along the full length or substantially the full length of the first heat pipe 444, the second heat pipe 446, or both, and through the flex sheet hollow connector 436. In examples, fiber wick 462 may the same or different from fiber wick 460. In examples, fiber wick 462 may include the same material as described for fiber wick 460. In examples, fiber wick 462 may be connected to the first and second heat pipes by any thermal process including thermosonic bonding, laser welding, brazing, or any other suitable thermal process. In examples, fiber wick 462 may also be connected and/or installed as described for wicks 428, 430, 452, and/or 454. In examples, when fiber wick 462 is present extending from the first heat pipe to the second heat pipe as illustrated in FIG. 4D, fiber wick 460 may be omitted. In examples, a thermal system 400 may include a combination of fiber wick 460 and fiber wick 462.

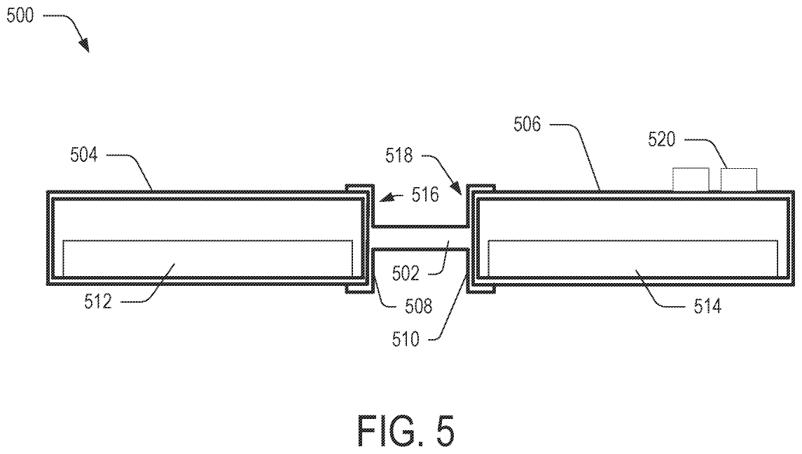

In examples, the thermal system 400 as described with reference to FIG. 4A, 4B, 4C, or 4D may employ the first heat pipe as an evaporation side and the second heat pipe as a condensation side. In examples, an electronic device may be equipped with a thermal system 400 and may include a heat pipe at a first location where heat is mostly generated, such as for example, proximate to and/or thermally coupled to one or more electronic components. In examples, another heat pipe of a thermal system 400 may be provided at a second location of the electronic device where heat is not generated and/or less heat is generated than the first location. In examples, the electronic device may include a curved portion and/or a mechanical articulation such as one provided by a coupler between the first location and the second location. In examples, the flexible portion or hollow connector of thermal system 400 may be arranged to correspond to the curved portion and/or mechanical articulation portion of the electronic device to accommodate the curved portion and/or mechanical articulation of the electronic device with minimal to no impedance imposed on the heat spreading functionality. 1001211 FIG. 5 illustrates an example of a thermal system 500 in which a solid connector 502 is used as the flexible portion of the thermal system. In examples, solid connector 502 may include a strip of thermally conductive material. In examples, solid connector 502 is a solid strip of material. In examples, solid connector 502 is not hollow.

In examples, solid connector 502 may include a material that has high thermal conductivity. In examples, the material may exhibit a thermal conductivity of at least 25 W/mK, for example 25 to 35 W/mK, or 35 to 40 W/mK. In examples, solid connector 502 may include a strip of metal. In examples, solid connector 502 may include titanium or a titanium alloy. In examples, solid connector 502 may include graphite or a graphite lining In examples, a solid connector 502 may include a titanium strip with graphite lining In examples, solid connector 502 may include a flexible circuit. Any combination of these materials and arrangements may be used.

In examples, the thermal system 500 may include one or more solid connectors 502 connecting a first heat pipe 504 to a second heat pipe 506. In examples, a solid connector 502 may be connected to one end of a first heat pipe 504 and to one end of a second heat pipe 506. In examples, first heat pipe 504 and second heat pipe 506 may each include an independently sealed, rigid structure. In examples, first heat pipe 504 and second heat pipe 506 may be the same or different and may include the same features as the heat pipes described earlier with reference to FIGS. 2A-4C. In examples, first heat pipe 504 and second heat pipe 506 may each include a wick 512 and 514. In examples, a solid connector 502 connects the two heat pipes. In examples, at least two solid connectors 502 connect the two heat pipes.

In examples, a solid connector 502 may have any cross-sectional shape. In examples, a solid connector 502 may include a cross-sectional shape that is circular or polygonal. In examples, a solid connector 502 may include a circular cross-section with a diameter ranging from about sub-millimeter to about 5 mm In examples, a circular cross-section with a diameter ranging from about 0.15 mm to 2 mm, or from about 2 mm to 5 mm, In examples, a circular solid connector 502 may have a diameter of about 3 mm.

In examples, a solid connector 502 may be configured to transfer heat from the first heat pipe 504 to the second heat pipe 506 such as to minimize the temperature difference between the temperature of first heat pipe 504 at the contact point with solid connector 502 and the temperature of the second heat pipe 506 at the contact point with the solid connector 502.

In examples, a solid connector 502 may be bonded at one end 508 to the first heat pipe 504 and at a second, opposite end 510 to the second heat pipe 506. In examples, the contact area 516 between end 508 and the first heat pipe 504 and/or the contact area 518 between end 510 and the second heat pipe 506 may be maximized. In examples, the contact area between end 508 and the first heat pipe 504 may be equal to the circumferential area of first heat pipe 504 at the point of contact. In examples, the contact area between end 510 and the second heat pipe 506 may be equal to the circumferential area of the second heat pipe 506 at the point of contact. In examples, the width of the contact area between solid connector 502 and a heat pipe is at least about 1 mm.

In examples, bonding between a solid connector 502 and a heat pipe may be effectuated via mechanical bonding, thermal bonding, ultrasound, adhesive including polymer adhesive, or any combination thereof. In examples, mechanical bonding may be effectuated, for example, by one or more fasteners such as screws, bolts, clamps, or similar device. In examples, thermal bonding may be effectuated by thermal process such as thermosonic bonding, laser welding, brazing, or any other suitable process. In example, a solid connector 502 and an outer shell of the heat pipe to be bonded to solid connector 502 may include common material, such as for example, the same metal. In examples, having the same material may strengthen the bond.

In examples, thermal system 500 does not include fluid flow through solid connector 502. In examples, in thermal system 500 there is no fluid flow between the first heat pipe 504 and the second heat pipe 506. In examples, the first heat pipe 504 and the second heat pipe 506 may be configured to operate independently. In examples, the heat transfer between the first heat pipe 504 and the second heat pipe 506 is only by way heat transfer by one or more solid connectors 502.

In examples, the engagement of one or more solid connectors 502 as a metal strip may allow for enhanced flexibility and enhanced cyclical endurance for thermal system 500.

In examples, the thermal system 500 as described with reference to FIG. 5 may employ the first heat pipe as primarily to collect heat and the second heat pipe to primarily spread heat. In examples, each heat pipe may include an evaporator side and a condenser side. In examples, solid connector 502 may be configured to transfer heat from the condenser side of one heat pipe to the evaporator side of the other heat pipe. In examples, an electronic device may be equipped with a thermal system 500 and may include one heat pipe at a first location where heat is mostly generated, such as for example, proximate to and/or thermally coupled to one or more electronic components 520. In examples, another heat pipe of a thermal system 500 may be provided at a second location of the electronic device where heat is not generated and/or less heat is generated than the first location. In examples, the electronic device may include a curved portion and/or a mechanical articulation such as one provided by a coupler between the first location and the second location. In examples, the flexible portion or solid connector of thermal system 500 may be arranged to correspond to and/or extend across and/or through the curved portion and/or mechanical articulation portion of the electronic device to accommodate the curved portion and/or mechanical articulation of the electronic device with minimal to no impedance imposed on the heat spreading functionality, or the operation of the mechanical articulation.

In examples, the structure of a thermal system as described with reference to FIGS. 2A-5 may include forming one or more heat pipes that either integrally include a bellows and/or are connected together by a connecting bellows, hollow connector, and/or solid connector.

Although different examples of thermal systems with a flexible portion have been described separately with reference to FIGS. 2A-5, in examples, a thermal system may be formed by combining two or more of these examples. For instance, any first and/or second heat pipe as discussed with reference to FIGS. 3-5 may include one or more integrated bellows as described with reference to FIGS. 2A-2B. In examples, three or more heat pipes may be connected in series wherein a first flexible portion may include one flexible portion independently selected from those described with reference to FIGS. 3-5 and a different second flexible portion may include an independently selected flexible portion from those described with reference to FIGS. 3-5. In examples, a thermal system may include any combination of two or more flexible portions each independently selected from those described with reference to FIGS. 2A-5.

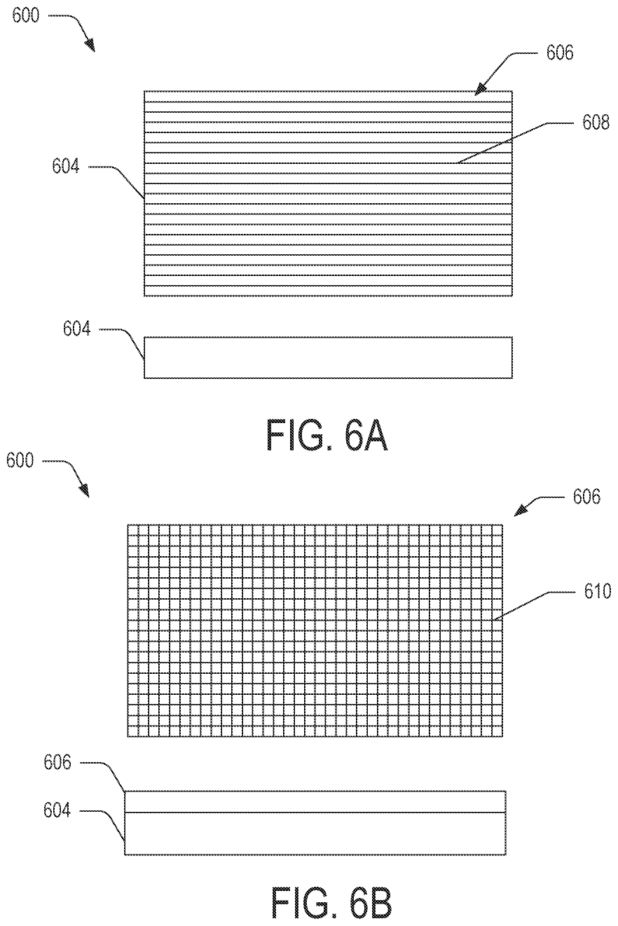

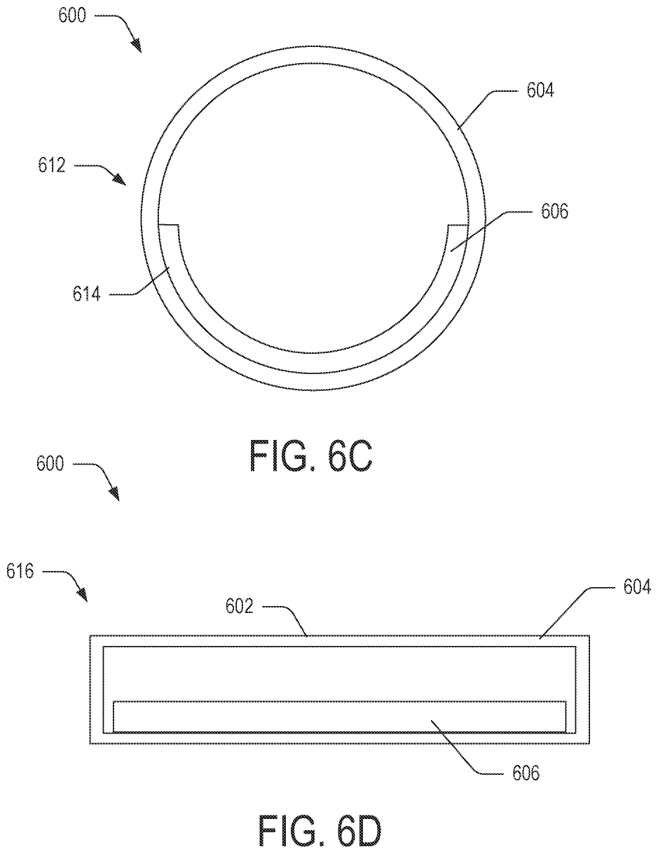

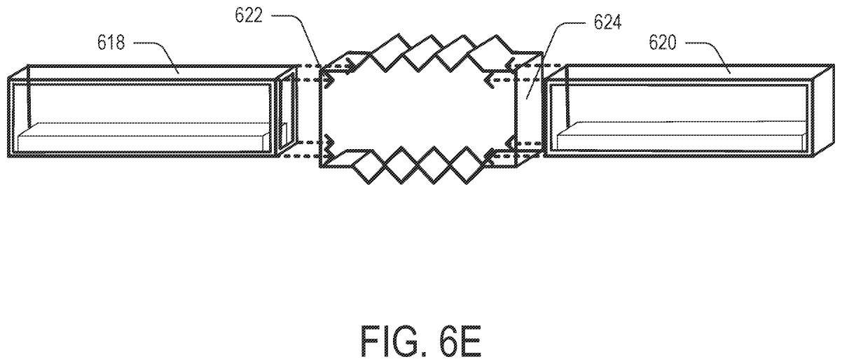

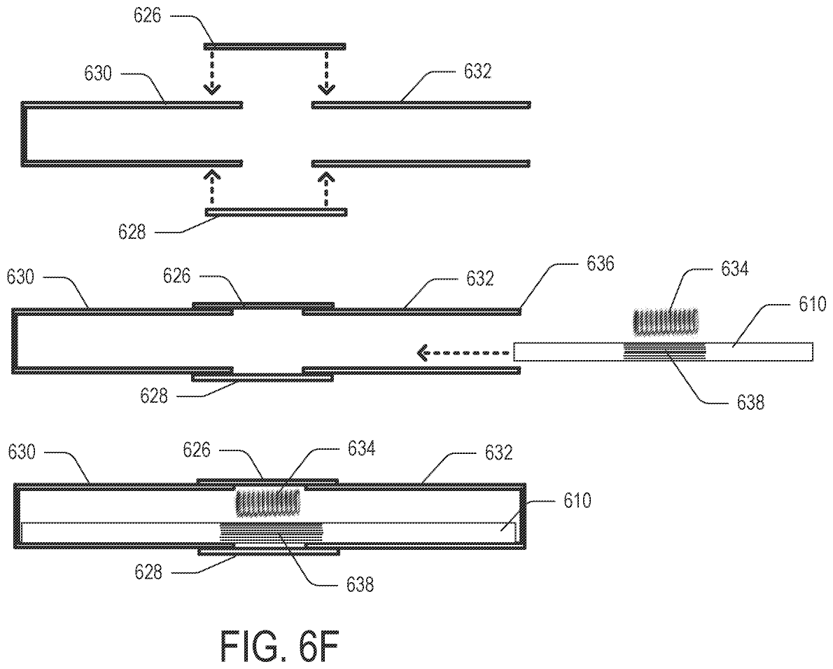

FIG. 6A-6D illustrate an example of a manufacturing process 600 for forming a thermal system as described. FIGS. 6A-6C are referenced in describing the process for building a thermal management component such as a heat pipe. FIGS. 6A and 6B each illustrates a top down view and a side view, while FIGS. 6C and 6D each illustrates a cross section of an example. In examples, a heat pipe 602 may be formed by taking a sheet of material 604 as previously described for a heat pipe outer shell. In examples, the sheet of material 604 may be a metal.

In examples, a wick 606 may be formed on the sheet of material 604. As previously described, a wick 606 may include a mesh, fiber, and/or corrugated capillary features. In examples, corrugated capillary features 608 may be formed by etching, laser ablation, or a combination thereof. In examples, the capillary features 608 may be formed by etching using a caustic solution such as KOH. In examples, one or more photolithography masks may be used to define the capillary features 608 to be etched. In examples, one or more capillary features 608 may be laser ablated. In examples, capillary features 608 may be formed by a combined process of laser ablation and chemical etching. Example process of forming capillary features 608 on a substrate is described in co-pending U.S. application Ser. No. 17/559,949, filed on Dec. 22, 2021, which incorporated herein by reference in its entirety. In examples, a mesh 610 as described herein may be thermosonically welded on the substrate to form at least a portion of wick 606. In examples, mesh 610 may be bonded directly to the sheet of material 604 without capillary features 608 or with capillary features 608 formed thereon. In examples, a mesh 610 may be thermosonically welded to sheet of material 604. In examples, a mesh 610 may be thermosonically welded over capillary features 608 formed on the sheet of material 604. In examples, mesh 610 may be replaced by fibers as previously described.

In examples, after the wick 606 is formed, the sheet of material 604 may be rolled and seam welded along its length to form a cylindrical structure 612. In examples, cylindrical structure 612 will be configured such that wick 606 is only over one internal portion of cylindrical structure 612. For example, wick 606 may extend across no more than half of an internal surface 614 of cylindrical structure 612. Optionally, in examples, cylindrical structure 612 may be compressed to change the circular cross-section into a quadrilateral cross-section 616 as illustrated in FIG. 6C. Once completed, the ends of a heat pipe may be sealed, a vacuum may be formed inside the heat pipe, and the heat pipe may be charged with a working fluid, for example, through a micro-metering valve.

In examples, when forming a thermal system as described in FIGS. 2A and 2B where a flexible portion such as a bellows is integrated in the thermal management component, the sheet of material 604 may be processed to include at least one portion to have a pleated profile as previously discussed. In examples, the process to form the pleats or folds may include a heat press, forging, casting, shearing, bending, or other metalworking processes that can achieve the pleated pattern. In examples, process of forming the pleats or folds may be performed before or after forming at least a portion of wick 606. In examples, the pleats or folds may be formed prior to bonding a mesh 610 to sheet of material 604 and/or prior to rolling the sheet of material 604 into a cylindrical structure 612 even if a mesh 610 is not added.

In examples, when forming a thermal system as described in FIGS. 3-5 where two or more thermal management components are connected with a flexible portion, the above describe manufacturing process with reference to FIGS. 6A-6D may be carried out to form a first thermal management component such as a first heat pipe and a second thermal management component such as a second heat pipe. Once at least two heat pipes are formed, the process may include connecting the two heat pipes via the flexible portion that may be a bellows, a hollow connector, or a solid connector as previously described.

In examples, as shown in FIG. 6E, where a connecting bellows is used as described with reference to FIG. 3 or where a hollow connector is used as described with reference to FIGS. 4A-4E, one end portion of each heat pipe 618 and 620 may be at least partially inserted into a mating end 622 and 624 of the connecting bellows or hollow connector and then bonded to form a hermetic seal.

In examples, where the hollow connector as previously described with reference to FIGS. 4A-4E is formed of two plates sealed along a seam, a first and second plate 626 and 628 may be brought together and sealed against each other and to an end portion of respective heat pipes 630 and 632 as illustrated in FIG. 6F. In examples, when bonded to end portions of respective heat pipes 630 and 632, the first and second plate 626 and 628 may form a seal around a full perimeter of each end portion of the respective heat pipes 630 and 632.

In examples, sealing of the first and second plate to each other may be accomplished via thermal bonding, one or more mechanical fasteners, adhesive, or any combination thereof as similarly described for the bonding a hollow connector to a heat pipe.

In examples, the bonding between heat pipes and the flexible portion may be performed mechanically, thermally, by adhesive, or any combination thereof as also previously described. In examples, where the flexible portion is configured to allow fluid flow between heat pipes, the ends of the heat pipes to be bonded to the flexible portion of the thermal system may be left open. In examples, for at least one heat pipe the end opposite the end to be bonded to the flexible portion may be sealed. In examples, for at least one heat pipe, both ends are left unsealed. In this manner the two heat pipes may be connected at an open end with the flexible portion of the thermal system and thus become in fluid communication with one another.

In examples, such as shown in FIG. 6F, addition of a wick such as a fiber or mesh 610 as described with reference to FIG. 6B and optionally of a spacer 634, and optionally a fiber wick 638 may be held off until after two or more heat pipes are connected together via a flexible portion and then be inserted at the unsealed end 636 of the at least one heat pipe bonded to the flexible portion of the thermal system after the two heat pipes are bonded to the flexible portion. In examples, the fiber wick 638 may have a length that is equal to the length of the flexible portion. In examples, the fiber wick 638 may have a length that is greater or smaller than that of the flexible portion.

In examples, the wick 610 may be bonded to an internal surface of the first heat pipe, second heat pipe, or both. A spacer 634 and/or a fiber wick 638 may optionally also be inserted together with or separately from the wick 610 via unsealed end 636 in the same manner and positioned at the flexible portion and bonded to the flexible portion and/or to wick 610 thermally, mechanically, and/or by adhesive as described for the bonding of the wick. In an alternative, spacer 634 and/or fiber wick 638 may be inserted prior to the bonding of the two plates to the heat pipes and/or prior to the connection between the heat pipes and the flexible portion. In examples, the combined wick 610 and fiber wick 638 may be formed and then inserted through unsealed end 636. For example, wick 610 and fiber wick 638 may be bonded together prior to insertion. In examples, fiber wick 638 may be bonded over wick 610 and/or under wick 610. In examples, wick 610 may include two portions bonded at respective opposite ends of a fiber wick 638. In examples, wick 610 is not used and only fiber wick 638 is inserted along with the optional spacer 634. In examples, wick 610 is itself a fiber wick that when inserted extends from one end of the first heat pipe to an opposite end of a second heat pipe, passing through the flexible portion. In examples, where wick 610 is itself a fiber wick, an additional fiber wick 638 may be optional. The end 636 through which the wick 610, spacer 634, and fiber wick 638 are inserted may then be sealed. A vacuum may be induced in the seal structure formed by the heat pipes connected by the flexible portion of the thermal system. In examples, the sealed heat pipes may be charged with a working fluid. In examples, the working fluid may be injected via an orifice or micro-metering valve.

In examples, where the flexible portion is a solid connector as described with reference to FIG. 5, the heat pipes to be connected via the solid connector may be fully completed, sealed, and charged as described with reference to FIGS. 6A-6D, prior to bonding them to the solid connector. In examples, the solid connector can be bonded to respective ends of the two heat pipes as previously described to form a flexible portion of the thermal system.

Examples described herein reference the thermal system as including a heat pipe with one bellows portion integrated therein or two heat pipes connected by a flexible portion. In examples, the thermal system may include a heat pipe with two or more bellows portions integrated therein. In examples, the thermal system may include three or more heat pipes connected in series via two or more flexible portions, for example by having a bellows, hollow connector, or solid connector provided between every two consecutive heat pipes. Also, any combination of heat pipes with integrated bellows portions and interconnected with one or more flexible portions may be implemented.

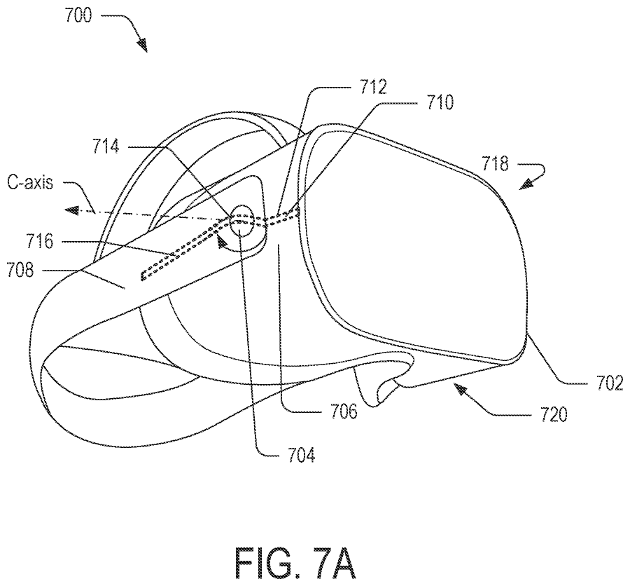

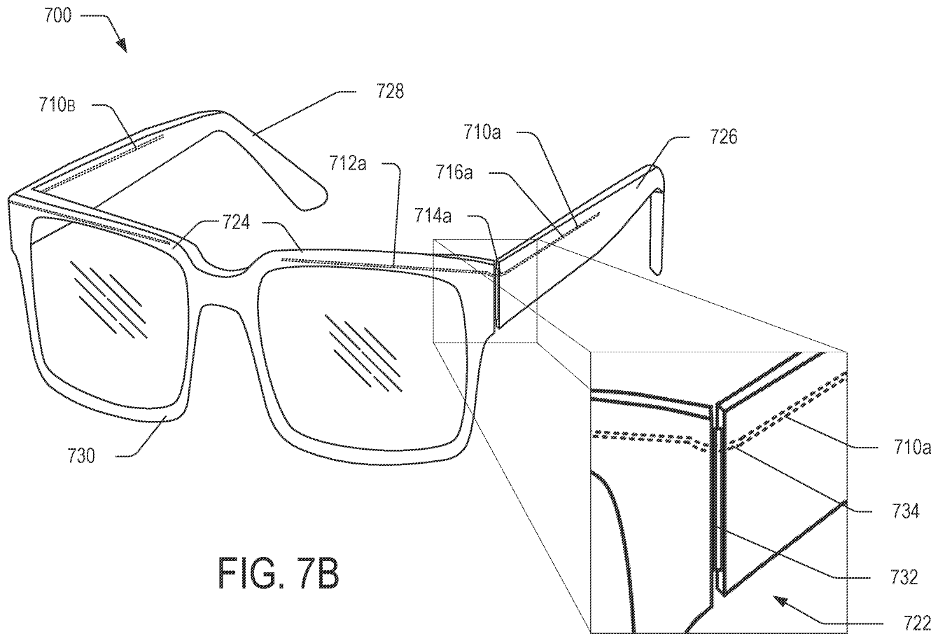

FIGS. 7A and 7B schematically illustrate examples of electronic device 700 that may be equipped with a thermal system as described with reference to FIGS. 2A-5 and manufactured in accordance with the description with reference to FIGS. 6A-6F. In examples, the electronic device may include a head mounted device as shown in FIGS. 7A and 7B in which a first elongated and/or planar portion may include a frame of the head-mounted device and a second elongated and/or planar portion may include a strap or temple arm of the head mounted device.

FIG. 7A illustrates a head mounted electronic device 700 in the form of an extended reality headset 702 that may include an articulated portion or strap. In examples, the extended reality headset 702 may include a first elongated and/or planar portion 706 and a second elongated and/or planar portion 708. In examples, first portion 706 may be frame portion of headset 702. In examples, second portion 708 may be a side or temple arm or portion of headset 702 such as for example a strap. In examples, a coupler 704 may be provided between the first portion 706 and the second portion 708 and configured to provide a mechanical articulation between the first portion 706 and the second portion 708. As illustrated, in examples, the coupler 704 may allow for a pivoting motion of second portion 708 about a central axis (C-axis) perpendicular to the first portion 706.

As shown, in examples, a thermal system 710 may be arranged so that a first portion 712 may be provided in first portion 706, a second portion 714 may extends along the mechanical articulation or coupler 704, and third portion 716 is provided in second portion 708.

In examples, the first portion 712 of thermal system 710 may include a first heat pipe or a first portion of a heat pipe. In examples, the second portion 714 of thermal system 710 may include a flexible portion that may include an integrated bellows, a connected bellows, a hollow connector, or a solid connector. In examples, the flexible portion of thermal system 710 may be configured to bend and/or flex to accommodate the pivoting articulation provided by coupler 704. In examples, the third portion 716 of thermal system 710 may include a second heat pipe or a second portion of a heat pipe.

In examples, as previously mentioned, additional heat pipes and/or portions of a heat pipe may be serially arranged in electronic device 700. For example, in extended reality headset 702, additional heat pipes or portions of heat pipes may be provided at a third portion 718 of the extended reality headset 702 wherein the third portion 718 is opposite the second portion 708 and connected to an opposite portion 720 of the electronic device frame from first portion 706 via a second coupler configured to provide a mechanical articulation. In examples, additional flexible portions of thermal system 710 may be arranged along the second coupler.

FIG. 7B illustrates another version of electronic device 700 in which one or more thermal systems 710 (e.g., 710a and 710b) may be employed. Shown in FIG. 7B is an electronic device with a mechanical articulation such as one provided by a coupler 722. In examples, the electronic device with mechanical articulation provided by a coupler 722 may include a type of extended reality glasses 730. In examples, the mechanical articulation by coupler 722 may include a rotating section such as a hinge 732 as previously described. In examples, a thermal system 710a may be arranged in extended reality glasses 730 such that a first portion 712a of a thermal system 710a may be provided at a first elongated and/or planar portion 724 of the extended reality glasses 730, a second portion 714a of thermal system 710a may include a flexible portion 734 arranged along or through the mechanical articulation provided by coupler 722, and a third portion 716a of thermal system 710a may be provided in second elongated and/or planar portion 726 of the extended reality glasses 730. In examples, first elongated and/or planar portion 724 in FIG. 7B may be a front face portion of an electronic device 700, and second elongated and/or planar portion 726 may be a side or temple arm or portion of the electronic device 700, wherein a mechanical articulation such as a coupler 722 is provided between first portion 724 and second portion 726. In examples, the coupler 722 may be configured to mechanically articulate the pivoting, swinging, and/or rotation of one second portion 726 with respect to first portion 724.

In examples, the flexible portion 734 of the thermal system 710a may be configured to bend as the mechanical articulation or coupler 722 pivots, swings, or rotates. In examples, three or more heat pipe sections and/or heat pipes may be serially arranged with flexible portions between any two sections or heat pipes arranged to correspond to the mechanical articulation or couplers 722.

Although as illustrated in FIGS. 7A and 7B an electronic device includes a separate thermal system 710 extending across mechanical articulation, in examples, two or more thermal systems 710 may be connected to each other. For example, in examples, thermal systems 710a and 710b, where a thermal system 710a extends from first portion 724 to second portion 726 of electronic device 700 and thermal system 710b extends from first portion 724 to third portion 728 of electronic device 700, as for example shown in FIG. 7B, could be operatively connected to each other. In examples, second portion 726 and third portion 728 may be opposite each other, such as for example, the temple arms or side or temple portions of an extended reality glasses 730 as illustrated in FIG. 7B both connected to a front portion 724 by respective couplers 722. In examples, two thermal systems 710a and 710b may be operatively, directly, and/or physically connected at first elongated and/or planar front portion 724. In examples, a connecting element such as a flexible portion of a thermal system as described here may form the connection between the two thermal systems. In examples, a heat pipe of one thermal system may extend across the first elongated and/or planar portion 724 and be connected at each mechanical articulation or coupler to respective second and third heat pipes by first and second flexible portions. In examples, the electronic device may thus include a thermal system with a single heat pipe with one or more integrated flexible portions, two heat pipes operably connected by one or more flexible portions, or three or more heat pipes operably connected by one or more flexible portions.

Also, in examples, although not illustrated electronic device 700 may be any other type of electronic device as previously described. In examples, an electronic device 700 may include both a static curved section and a mechanical articulation. A thermal system may be arranged within such electronic device having both a static curved section and a mechanical articulation in the same manner as described.

Although the discussion above sets forth example implementations of the described techniques and structural features, other architectures may be used to implement the described functionality and are intended to be within the scope of this disclosure. Furthermore, although the subject matter has been described in language specific to structural features and/or methodological acts, it is to be understood that the subject matter defined in the appended claims is not necessarily limited to the specific features or acts described. Rather, the specific features and acts are disclosed as exemplary forms of implementing the claims. For example, the structural features and/or methodological acts may be rearranged and/or combined with each other and/or other structural features and/or methodological acts. In various examples, one or more of the structural features and/or methodological acts may be omitted.

What is claimed is:

1. An electronic device comprising:
a first elongated portion;
a second elongated portion;
a coupler interposed between the first elongated portion and the second elongated portion, the coupler attached to the first elongated portion and the second elongated portion and configured to provide mechanical articulation of the second elongated portion relative to the first elongated portion; and
a thermal system extending from the first elongated portion to the second elongated portion and configured to extend across the coupler, the thermal system comprising a flexible portion having a fiber wick extending through at least a portion of a hollow internal space of the flexible portion.

2. The electronic device of claim 1, the thermal system further comprising a first thermal management component comprising a first heat pipe, a first vapor chamber, or both.

3. The electronic device of claim 2, further comprising a bellows as an integral part of the first thermal management component.

4. The electronic device of claim 2, the thermal system further comprising a second thermal management component comprising a second heat pipe, second vapor chamber, or both.

5. The electronic device of claim 4, wherein the flexible portion is connected to one end of the first thermal management component and one end of the second thermal management component.

6. The electronic device of claim 5, the flexible portion comprising a connecting bellows comprising nickel.

7. The electronic device of claim 5, the flexible portion comprising a hollow connector.

8. The electronic device of claim 7, the hollow connector comprising a polypropylene, a polyethylene terephthalate, or a polyimide.

9. The electronic device of claim 8, wherein the polyimide comprises a metal laminated poly-oxydiphenylene-pyromellitimide.

10. The electronic device of claim 8, the polyethylene terephthalate comprises a molecular weight of at least about 5,000,000 gr/mol.

11. The electronic device of claim 4, the thermal system further comprising at least one of a mesh wick extending from the first thermal management component to the second thermal management component and through the flexible portion.

12. The electronic device of claim 1, the fiber wick comprises a metal coating.

13. The electronic device of claim 1, wherein the first elongated portion comprises a portion of a frame of a head-mounted device and the second elongated portion comprises a strap or temple arm of the head mounted device.

14. A bendable thermal system comprising:
a first longitudinal end;
a second longitudinal end;
a flexible portion disposed between the first longitudinal end and the second longitudinal end; and
a fiber wick provided inside the flexible portion.

15. The bendable thermal system of claim 14, the flexible portion comprising polyethylene terephthalate having a thermal conductivity of 25 W/mK or higher.

16. The bendable thermal system of claim 14, wherein the flexible portion comprises a metal laminated polyimide.

17. The bendable thermal system of claim 14, wherein the flexible portion comprises nickel.

18. The bendable thermal system of claim 14, further comprising a thermal management component selected from a single heat pipe or a single vapor chamber, wherein the thermal management component comprises the first longitudinal end and the second longitudinal end.

19. A bendable thermal system comprising:
a first thermal management component comprising a first sealed, rigid structure;
a second thermal management component comprising a second sealed rigid structure; and
a solid connector connected to one end of the first thermal management component and to one end of the second thermal management component, the solid connector configured to transfer heat from the first thermal management component to the second thermal management component.

20. The bendable thermal system of claim 19, wherein the solid connector comprises graphite, titanium, or a combination thereof.
